(19) United States
(12) Patent Application Publication
(10) Pub. No.: US 2013/0125987 A1
(43) Pub. Date: May 23, 2013

(54) PHOTOELECTRIC CONVERSION ELEMENT AND SOLAR BATTERY CONTAINING THE SAME

(71) Applicants: Hidekazu KAWASAKI, Tokyo (JP); Kazukuni NISHIMURA, Tokyo (JP); Hideya MIWA, Tokyo (JP)

(72) Inventors: Hidekazu KAWASAKI, Tokyo (JP); Kazukuni NISHIMURA, Tokyo (JP); Hideya MIWA, Tokyo (JP)

(21) Appl. No.: 13/673,482

(22) Filed: Nov. 9, 2012

(30) Foreign Application Priority Data
Nov. 21, 2011 (JP) 2011-254284

(51) Int. Cl. H01L 51/00; H01L 51/42

(52) U.S. Cl. CPC H01L 51/0036; H01L 51/0035; H01L 51/42
USPC 136/263

(57) ABSTRACT

The object is to provide a photoelectric conversion element having excellent photoelectric conversion efficiency, and high durability.

A photoelectric conversion element comprising a substrate, a first electrode, a photoelectric conversion layer containing a semiconductor and a sensitizing dye, a hole transport layer, and a second electrode, in which the sensitizing dye is represented by the following Chemical Formula (1):

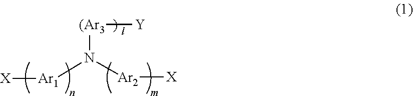

### CROSS-REFERENCE TO RELATED APPLICATION

This application is based on Japanese Patent Application No. 2011-254284 filed on Nov. 21, 2011, the contents of which are incorporated herein by reference.

### BACKGROUND

1. Technical Field

The present invention relates to a photoelectric conversion element and a solar battery containing the same.

2. Description of Related Arts

In recent years, the use of sunlight, which is infinite and does not generate toxic substances, is being actively considered. An example of an application method of this clean energy source, sunlight, is the application to solar batteries using the photovoltaic effect. The photovoltaic effect is a phenomenon in which electromotive force is generated by irradiating a substance with light, and by using a photoelectric conversion element containing the substance, it is possible to convert light energy into electrical energy. An inorganic solar battery which uses photoelectric conversion elements which contain mainly inorganic materials such as monocrystalline silicon, polycrystalline silicon, amorphous silicon, cadmium telluride, and copper indium selenide is realized as a solar battery. However, in the inorganic solar battery, the inorganic materials which are used are required to be of a high purity, therefore there are drawbacks such as the manufacturing process becoming complicated and the manufacturing cost being high.

As a method of solving the above drawbacks of inorganic solar batteries, an organic solar battery using an organic material for the photoelectric conversion element is proposed. Examples of the organic material include, for example, a Schottky-type photoelectric conversion element in which a p-type organic semiconductor and a metal having a low work function are joined; and a heterojunction-type photoelectric conversion element in which a p-type organic semiconductor and an n-type inorganic semiconductor, or a p-type organic semiconductor and an electron-accepting organic compound are joined. As the organic semiconductor contained in the photoelectric conversion element, a synthetic dye or pigment such as chlorophyll and perylene, a conductive polymer material such as polyacetylene, a composite material of these or the like is used. Furthermore, these materials are made into thin films using a vacuum deposition method, a casting method, a dipping method, or the like, and applied to a solar battery. For organic solar batteries, it becomes possible to reduce the cost and increase the surface area, however, the photoelectric conversion efficiency is low at 1% or less, and there is a problem with durability.

Under such circumstances, a solar battery which exhibits favorable characteristics is reported by the Swiss Doctor Gratzel et al. (for example, refer to Nature, 353, 737 (1991), B. O'Regan, M. Gratzel). The solar battery is a dye sensitization-type solar battery and, more specifically, is a liquid junction solar battery, in which the working electrode is a titanium oxide porous thin film which is spectrally sensitized by a ruthenium complex. Examples of merits of this solar battery are that it is unnecessary to increase purity as in the above described inorganic material due to being able to use a low cost metal compound such as a titanium oxide as the semiconductor material, and that the usable wavelength of light spans into the visible light region due to the dye sensitization effect of the ruthenium complex. Accordingly, the dye sensitization-type solar battery has a low manufacturing cost in comparison with the inorganic material, and it is possible to effectively convert sunlight energy, which has a large visible light component, into electrical energy.

However, there is an extremely small amount of ruthenium on Earth, the produced amount being a few tons per year. Therefore, for the practical use of dye sensitization-type solar batteries using ruthenium, there were problems such as ruthenium having a high cost and there being a possibility that the supply amount will be insufficient. In addition, the stability of a ruthenium complex over time is low, therefore, there are also problems in application to solar batteries from a viewpoint of durability. Therefore, a sensitizing dye which may be supplied in large quantities at a low cost and has durability to replace ruthenium complexes is in demand.

From such circumstances, as a sensitizing dye to replace a ruthenium complex, for example, a liquid junction solar battery using a phthalocyanine compound is disclosed in Japanese Patent Application Laid-Open (JP-A) No. 9-199744. The phthalocyanine compound described in JP-A No. 9-199744 can improve the durability of the solar battery due to being able to form a strong adsorption bonded state with a titanium dioxide surface (semiconductor). However, the absorption wavelength region of the phthalocyanine compound described in JP-A No. 9-199744 is narrow, and there is a problem in that the phthalocyanine compound could not sufficiently absorb sunlight, which has a wide spectrum.

Therefore, in recent years, a method of adsorbing a plurality of different sensitizing dyes onto a semiconductor has been proposed (for example, refer to JP-A Nos. 2003-249279, 2006-185911, J. Phys. Chem. B., 105,9960 (2001), A. Ehret, M. T. Spitler, and New. J. Chem., 29,773 (2005), Y. Chen, B. Zhang). According to this method, the absorption wavelength region may be lengthened by applying the plurality of senstizing dyes; however, the adsorption power with the sensitizing dye and the semiconductor is weak, and there are reports that problems occur with the durability.

In addition, in J. Phys. Chem. B., 107,597 (2003), K. Hara, H. Arakawa, and J. Am, Chem. Soc., 126,1221.8 (2004), T. Horiuchi, S. Uchida, there are reports that a photoelectric conversion element, which contains a sensitizing dye which has both a π electron conjugated system and an acidic adsorption group having electron attractiveness, exhibits a high photoelectric conversion efficiency of from 5% to 9%.

### SUMMARY

As described above, the photoelectric conversion elements which have been reported hitherto have problems such as having durability, however, having a narrow sensitizing dye light absorption wavelength region, or containing a sensitizing dye which may absorb light of a wide wavelength, however having an insufficient durability. Taking into consideration the application to solar batteries, a photoelectric conversion element, in which sunlight, which has a wide spectrum, may be efficiently used, and which may be used for a long period of time, was in demand.

Therefore, the object of the present invention is to provide a photoelectric conversion element with excellent photoelectric conversion efficiency, and having high durability.

The inventors, as a result of diligent research, have ascertained that the photoelectric conversion efficiency and the durability of a photoelectric conversion element can be significantly improved by applying a sensitizing dye of a specific structure to a photoelectric conversion element, thereby completing the present invention.

To achieve at least one of the above-mentioned objects, a photoelectric conversion element reflecting one aspect of the present invention includes the following characteristics.

In other words, a photoelectric conversion element includes a substrate, a first electrode, a photoelectric conversion layer containing a semiconductor and a sensitizing dye, a hole transport layer, and a second electrode, in which the sensitizing dye is represented by the following Chemical Formula (1):

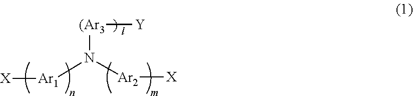

wherein, Ar₁, Ar₂, and Ar₃ are each independently a divalent aromatic ring-containing group, or a divalent unsaturated hydrocarbon group, and, Ar₁, Ar₂, and Ar₃ which are bonded to the nitrogen atom are a divalent aromatic ring-containing group, provided that the Ar₁, Ar₂, and Ar₃ may form a ring together,

n is an integer of from 1 to 9, and when n is 2 or greater, the respective Ar₁s may be different from each other, m is an integer of from 1 to 9, and when m is 2 or greater, the respective Ar₂s may be different from each other, 1 is an integer of from 1 to 5, and when 1 is 2 or greater, the respective Ar₃s may be different from each other, and in this case, m+n 3 is satisfied, and when m=n, −(Ar₁)ₙ— and —(Ar₂)ₘ— are different from each other,

X is a monovalent substituent containing an acidic group, and

Y is a hydrogen atom or a monovalent substituent.

### BRIEF DESCRIPTION OF THE DRAWINGS

FIG. 1 is a cross section view schematically representing the photoelectric conversion element according to an embodiment of the present invention. In the FIG. 1, symbol 1 stands for a substrate; 2 for a first electrode; 3 for a barrier layer; 4 for a sensitizing dye; 5 for a semiconductor; 6 for a photoelectric conversion layer; 7 for a hole transport layer; 8 for a second electrode; 9 for an incidence direction of solar light; and 10 for a photoelectric conversion element.

### DETAILED DESCRIPTION

In the present invention, the photoelectric conversion element includes a substrate, a first electrode, a photoelectric conversion layer containing a semiconductor and a sensitizing dye, a hole transport layer, and a second electrode, and the sensitizing dye is represented by the Chemical Formula (1) above.

The photoelectric conversion element according to the present invention is characterized by —(Ar₁)ₙ— and —(Ar₂)ₙ— being different from one another in the sensitizing dye represented by the above Chemical Formula (1). Accordingly, the absorption wavelength region is lengthened, and since it is possible to efficiently use light having a wide spectrum, the photoelectric conversion element which has the sensitizing dye can achieve a high photoelectric conversion efficiency. In addition, the sensitizing dye represented by the above Chemical Formula (1) is characterized by incorporating a monovalent substituent X containing two of the same acidic groups. Accordingly, the durability of the photoelectric conversion element may be improved due to being able to stably adsorb the sensitizing dye onto the semiconductor.

Hereinafter, the present invention will be described in detail.

### [Photoelectric Conversion Element]

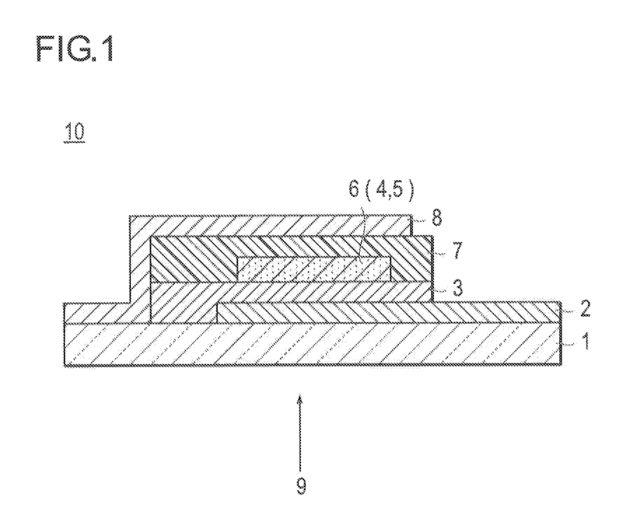

The photoelectric conversion element of the present invention will be described with reference to FIG. 1. FIG. 1 is a cross section view schematically representing the photoelectric conversion element according to an embodiment of the present invention. As shown in FIG. 1, a photoelectric conversion element 10 has a configuration in which it is formed by laminating a substrate 1, a first electrode 2, a barrier layer 3, a photoelectric conversion layer 6, a hole transport layer 7, and a second electrode 8, in this order. Here, the photoelectric conversion layer 6 contains a semiconductor and a sensitizing dye 4. As shown in FIG. 1, the barrier layer 3 may be included between the first electrode 2 and the photoelectric conversion layer 6, in order to prevent short circuiting, provide sealing, or the like. Furthermore, in FIG. 1, the sunlight enters from the direction of arrow 9 in the lower side of the drawing, however, the present invention is not limited to this form, and sunlight may also be incident from the upper side of the drawing.

Next, a preferable embodiment of the manufacturing method of the photoelectric conversion element according to the present invention will be described. First, after forming the barrier layer 3 on the substrate 1, on which the first electrode 2 was formed, a semiconductor layer formed from the semiconductor 5 is formed on the barrier layer 3, and the sensitizing dye 4 is adsorbed to the semiconductor surface thereof to form the photoelectric conversion layer 6. Subsequently, the hole transport layer 7 is formed on the photoelectric conversion layer 6. In this case, the hole transport layer 7 infiltrates the photoelectric conversion layer 6, which is formed from the semiconductor 5 which supports the sensitizing dye 4, and is present on the photoelectric conversion layer 6. Furthermore, the second electrode 8 is formed on the hole transport layer 7. A current can be extracted by attaching terminals to the first electrode 2 and the second electrode 8.

Hereinafter, each member of the photoelectric conversion element of the present invention will be described.

### [Substrate]

The substrate has a role as a coating liquid coated member in a case where the electrodes are formed using a coating method. When light is incident from the substrate side, it is preferable for the substrate to be a member through which it is possible to transmit the light, in other words, is transparent in relation to the wavelength of light which is to be photoelectrically converted. Specifically, from a viewpoint of the photoelectric coversion efficiency; the optical transmittance is preferably 10% or greater, more preferably 50% or greater, and particularly preferably from 80% to 100%. Furthermore, in the present specification, the term “optical transmittance” means the total luminous transmittance measured in a visible light wavelength region using a method based on “Plastics—Determination of the total luminous transmittance of transparent materials” of JIS K 7361-1:1997 (equivalent to ISO 13468-1:1996).

For the substrate, a publicly known material, shape, structure, thickness, hardness, and the like may be appropriately selected, however, it is preferable that the optical transmittance thereof be high, as described above.

As the material of the substrate, a substrate having stiffness, and a substrate having flexibility may be used. A substrate having stiffness and a substrate having flexibility may also be combined and used together. There are no particular limitations to the substrate having stiffness, and a publicly known substrate may be used. Specifically, a glass plate and an acryl plate may be exemplified. Among these, it is preferable to use a glass plate from the viewpoint of heat resistance. There are no particular limitations to the substrate having flexibility, and a publicly known substrate may be used. Specifically, examples thereof include polyester-based resin films such as polyethylene terephthalate (PET), polyethylene naphthalate, and modified polyester; polyolefin-based resin films such as polyethylene (PE), polypropylene (PP); polystyrene, and cyclic olefin; vinyl-based resin films such as polyvinyl chloride, and polyvinylidene chloride; polyvinyl acetal resin films such as polyvinyl butyral (PVB); polyether ether ketone (PEEK) resin film; polysulfone (PSF) resin film; polyethersulfone (PES) resin film; polycarbonate (PC) resin film; polyamide resin film; polyimide resin film; acrylic resin film; and triacetyl cellulose (TAC) resin film.

Furthermore, in consideration of using sunlight energy, a resin film, in which the transmittance at a visible region wavelength (from 400 nm to 700 nm) is 80% or greater, may also be used as the substrate. Examples of the resin film include a biaxially oriented polyethylene terephthalate film, a biaxially oriented polyethylene naphthalate film, a polyether sulfone film, a polycarbonate film, and the like, and among these, it is preferable to use the biaxially oriented polyethylene terephthalate film, and the biaxially oriented polyethylene naphthalate film.

The thickness of the substrate is not particularly limited, however, it is preferably from 1 μm to 1500 μm, and more preferably from 10 μm to 0.100 μm.

Surface treatment and an easy adhesion layer may also be provided to the above substrate in order to secure the wettability and adhesiveness of the coating liquid. Publicly known technology of the related art may be used for the surface treatment and the easy adhesion layer. For example, surface treatment may be performed by using surface activation treatment such as corona discharge treatment, flame treatment, ultraviolet treatment, high frequency processing, glow discharge treatment, active plasma treatment, and laser treatment. In addition, a polyester, a polyamide, a polyurethane, a vinyl-based copolymer, a butadiene-based copolymer, an acrylic-based copolymer, a vinylidene-based copolymer, an epoxy-based copolymer, and the like may be used as the easy adhesion layer.

### [First Electrode]

The first electrode is arranged between the substrate and the photoelectric conversion layer. Here, the first electrode is provided on one surface, which is the opposite side to the light incidence direction of the substrate. In the first electrode, from a viewpoint of the photoelectric conversion efficiency, the optical transmittance is preferably 10% or greater, more preferably 50% or greater, and particularly preferably from 80% to 100%.

There are no particular limitations to the material which configures the first electrode, and a publicly known material may be used. For example, a metal and the oxide thereof, and a composite (doping) material which contains at least one type selected from a group formed from Sn, Sb, F, and Al may be used. Examples of the metal include platinum, gold, silver, copper, aluminum, rhodium, and indium. Examples of the metallic oxides include SnO₂, CdO, ZnO, CTO-based (CdSnO₃, Cd₂SnO₄, CdSnO₄), In₂O₃, and CdIn₂O₄ and examples of the composite (doping) material include In₂O₃ (ITO) doped with Sn, SnO₂ doped with Sb, and SnO₂ (FTO) doped with F.

The coating amount of the material to form the first electrode to the substrate is not particularly limited, however, it is preferably approximately from 1 g to 100 g per 1 m² of substrate. Furthermore, in the present specification, the laminated body, which is formed by the substrate and the first electrode formed thereon, is also referred to as the “conductive support body”.

The film thickness of the conductive support body is not particularly limited, however, it is preferably from 0.1 mm to 5 mm. The surface resistance value of the conductive support body is preferably the lowest possible value. Specifically, the surface resistance value is preferably 500 Ω/square or less, and more preferably 10 Ω/square or less.

### [Barrier Layer]

The barrier layer is an arbitrary configuration element provided from a viewpoint of preventing a short circuit caused by the recombination of a hole, which is generated by the reception of light and injected into the hole transport layer, electrons of the first electrode, and the like. The barrier layer may be arranged in a film shape (layer shape) between the first electrode and the photoelectric conversion layer described below.

There are no particular limitations to the configuration material of the barrier layer, and a publicly known material may be used. Among these, a material having equivalent electrical conductivity to the semiconductor material of the photoelectric conversion layer is preferable. Specifically, examples thereof include metals such as zinc, niobium, tin, titanium, vanadium, indium, tungsten, tantalum, zirconium, molybdenum, manganese, iron, copper, nickel, iridium, rhodium, chromium, and ruthenium, or oxides thereof; perovskites such as strontium titanate, calcium titanate, barium titanate, magnesium titanate, and strontium niobate, or composite oxides or oxide mixtures thereof; and metallic compounds such as CdS, CdSe, TiC, Si₃N₄, SiC, and BN. These materials may be used either in isolation and may also be used in a combination of two or more types.

When the hole transport layer is an oxidation-reduction electrolyte (a liquid electrolyte), a barrier layer may be provided or not provided, however, it is preferable to provide a barrier layer. On the other hand, when the hole transport layer is a p-type semiconductor (a solid electrolyte), it is preferable to provide a barrier layer. When a p-type semiconductor is used for the hole transport layer and a metal is used for the barrier layer, it is preferable to use a barrier layer in which the value of the work function is smaller than that of the hole transport layer and which performs Schottky-type contact. In addition, when a metallic oxide is used for the barrier layer, it is preferable to use a barrier layer which makes ohmic contact with a transparent conductive layer, and the energy level of the conduction band is lower than that of the semiconductor layer. It is also possible to improve the electron transfer efficiency from the porous semiconductor layer (photoelectric conversion layer) to the barrier layer by selecting the oxide which is used.

It is preferable for the barrier layer to be porous in addition to the semiconductor layer in the photoelectric conversion layer described below. In this case, when the porosity of the barrier layer is C [%] and the porosity of the semiconductor layer is [%], the D/C value is preferably 1.1 or greater, more preferably 5 or greater, and even more preferably 10 or greater. In order to set the D/C value to the above values, the porosity C of the barrier layer is preferably 20% or less, more preferably 5% or less, and even more preferably 2% or less. In other words, the barrier layer is preferably a compact layer (a compact porous shape). Accordingly, the barrier layer may effectively exhibit a short circuiting prevention effect.

There are no particular limitations to the average thickness of the barrier layer (film thickness) as long as a short circuiting prevention effect may be exhibited. Specifically, the film thickness is preferably from 0.01 μm to 10 μm, and more preferably from 0.03 μm to 0.5 μm.

### [Photoelectric Conversion Layer]

The photoelectric conversion layer has a function of converting light energy to electrical energy by using the photovoltaic effect. In the present invention, it is essential that the photoelectric conversion layer contains a semiconductor and a sensitizing dye. More specifically, the photoelectric conversion layer has a configuration in which the sensitizing dye is supported in the semiconductor layer containing the semiconductor.

### (Semiconductor)

As the material of the semiconductor used in the semiconductor layer, it is possible to use simple substances such as silicon and germanium; compounds having elements of from group 3 to group 5 and from group 13 to group 15 of the periodic table (also known as the periodic table of elements); chalcogenides of metals (for example, oxides, sulfates, selenides, and the like); and metal nitrides. Specific examples of chalcogenides of metals include an oxide of titanium, tin, zinc, iron, tungsten, zirconium, hafnium, strontium, indium, cerium, yttrium, lanthanum, vanadium, niobium, or tantalum; a sulfide of cadmium, zinc, lead, silver, antimony or bismuth; a selenide of cadmium or lead; and a telluride of cadmium. In addition, examples of another material of the semiconductor include phosphides of zinc, gallium, indium, cadmium, and the like; selenides of gallium-arsenic copper-indium; sulfides of copper-indium; and nitrides of titanium. More specific examples include TiO₂, SnO₂, Fe₂O₃, WO₃, ZnO, Nb₂O₅, CdS, ZnS, PbS, Bi₂S₃, CdSe, CdTe, GaP, InP, GaAs, CulnS₂, CuInSe₂, and Ti₃N₄. Among these, using TiO₂, ZnO, SnO₂, Fe₂O₃, WO₃, Nb₂O₅, CdS, or PbS is preferable, using TiO₂ or Nb₂O₅ is more preferable, and using TiO₂ (titanium oxide) is particularly preferable. These materials may be used either in isolation and may also be used in a combination of two or more types. Examples of forms in which two or more types are combined include, for example, a form in which 20% by weight of titanium nitride (Ti₃N₄) is mixed into a titanium oxide semiconductor, and a form which is the zinc oxide/tin oxide composite disclosed in J. Chem. Soc. Chem. Commun., 15 (1999). Furthermore, when another semiconductor material is combined with a metallic oxide or a metallic sulfide and used, the weight ratio of the other semiconductor material is preferably 30% or less in relation to the metallic oxide or the metallic sulfide semiconductor.

The shape of the semiconductor is not, particularly limited and may be an arbitrary shape such as a spherical shape, a columnar shape, or a tubular shape. The size of the semiconductor is also not particularly limited, and, for example, when the semiconductor is a spherical shape, the average particle diameter of the semiconductor is preferably from 1 nm to 5000 nm, and more preferably from 2 nm to 500 nm. Furthermore, the term “average particle diameter” of the above semiconductor means the average particle diameter of the primary particle diameter (the primary average particle diameter) when 100 or more samples have been observed using an electron microscope.

The above semiconductor may also be surface treated using an organic base. Organic bases which may be used for surface treatment are not particularly limited, and examples thereof include diarylamine, triarylamine, pyridine, 4-tert-butyl pyridine, polyvinylpyridine, quinoline, piperidine, and amidine. Among these, it is preferable to perform surface treatment using pyridine, 4-tert-butyl pyridine, or polyvinylpyridine. The surface treatment method is not particularly limited, and a publicly known method may be used, and a person skilled in the art may change the method appropriately as necessary. For example, an example of a surface treatment method of the semiconductor includes a method of preparing a solution containing an organic base (an organic base solution) and immersing the semiconductor in the organic base solution.

### (Sensitizing Dye)

The sensitizing dye has a function of being photo-excited and generating electromotive force when light is irradiated thereto. The sensitizing dye is supported in the semiconductor by the sensitizing treatment of the semiconductor described below. The sensitizing dye used in the present invention is represented by Chemical Formula (1) below.

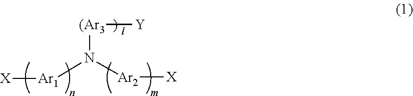

The sensitizing dye according to the present invention is characterized by —(Ar₁)ₙ— and —(Ar₂)ₘ— being different from one another in the above Chemical Formula (1). Accordingly, since the absorption wavelength of the sensitizing dye is lengthened, the photoelectric conversion efficiency of the photoelectric conversion element containing the sensitizing dye may be improved in relation to sunlight. In addition, the sensitizing dye according to the present invention in the above Chemical Formula (1) is also characterized by the monovalent substituents X incorporating two of the acidic groups being the same. Accordingly, the durability of the photoelectric conversion element may be improved due to an increase in adsorption stability between the sensitizing dye and the above described semiconductor.

In the above Chemical Formula (1), Ar₁, Ar₂, and Ar₃ are each independently a divalent aromatic ring-containing group, or a divalent unsaturated hydrocarbon group, and, the Ar₁, Ar₂, and Ar₃ which are bonded to a nitrogen atom are divalent aromatic ring-containing groups, provided that the Ar₁, Ar₂, and Ar₃ may also form a ring together. As described above, the Ar₁, Ar₂, and Ar₃ may contribute to a widening of the absorption wavelength. In general, when the number of multiple bonds which are conjugated within a molecule increases, the distance that an electron moves becomes longer, and an absorption band appears in the long wavelength side. This may also be understood, for example, from the fact that the maximum absorption wavelength of benzene is 261 nm, the maximum absorption wavelength of naphthalene is 312 nm, and the maximum absorption wavelength of anthracene is 375 nm. The sensitizing dye exhibits a wide absorption peak including visible light of sunlight due to the sensitizing dye having a different absorption region within the molecules, and it is possible to improve the photoelectric conversion efficiency of the photoelectric conversion element containing the sensitizing dye in relation to sunlight. According to the above, Ar₁, Ar₂, and Ar₃ contribute to wavelength lengthening of the absorption region of the sensitizing dye, and as long as they have a conjugated z bond, there are no particular limitations. Therefore, in the present specification, the Ar₁, Ar₂, and Ar₃ may perform wavelength lengthening on the absorption wavelength region of the sensitizing dye by expanding the π conjugated system. In the present specification, the “aromatic ring-containing group” is not particularly limited, however, examples thereof include benzene, naphthalene, anthracene, phenanthrene, pyrrole, furan, thiophene, pyridine, pyrazine, pyrimidine, pyridazine, triazine, imidazole, pyrazole, oxazole, isoxazole, thiazole, benzofuran, isobenzofuran, benzothiophene, benzo (c) thiophene, benzimidazole, benzoxazole, benzoisoxazole, benzothiazole, indole, fluorene, phthalazine, cinnoline, quinazoline, carbazole, carboline, diazacarboline (a carboline in which an arbitrary carbon atom has been replaced with a nitrogen atom), 1,10-phenanthroline, quinone, coumarin, rhodanine, dirhodanine, thiohydantoin, pyrazolone, pyrazoline, and groups derived from the compounds represented by the Chemical Formulas 4-1 or 4-2 below.

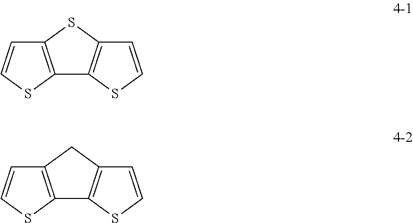 [SMILES: c1cc2sc3ccsc3c2s1 ; c1cc2c(s1)-c1sccc1C2]

In addition, in the present specification, the term “unsaturated hydrocarbon group” refers to a hydrocarbon group which has at least one double bond. Unsaturated hydrocarbon groups are not particularly limited, however, specific examples thereof include groups derived from ethylene, butadiene, hexatriene, and octatetraene.

Here, the number of repetitions of the “aromatic ring-containing group” is counted where one ring or one condensed ring is set to one unit. For example, one ring of benzene, pyridine, pyrimidine, pyrazine, thiophene, furan, pyrrole, or the like; and a condensed ring of naphthalene, benzothiophene, or the like are counted as one Ar. A biphenyl, a bithiophene, or the like to which these are bonded is counted as two Ar.

In addition, for the number of repetitions of the “unsaturated hydrocarbon group”, one group which is conjugated by double bonding is counted as one unit regardless of the number of double bonds. For example, when the “unsaturated hydrocarbon group” is interposed between “aromatic ring-containing groups”, as for the “unsaturated hydrocarbon group”, Ar is counted as one in relation to the portion interposed between aromatic ring-containing groups, regardless of the number of double bonds.

Specific examples of the number of repetitions of Ar are shown below.

### Examples with 1 Ar

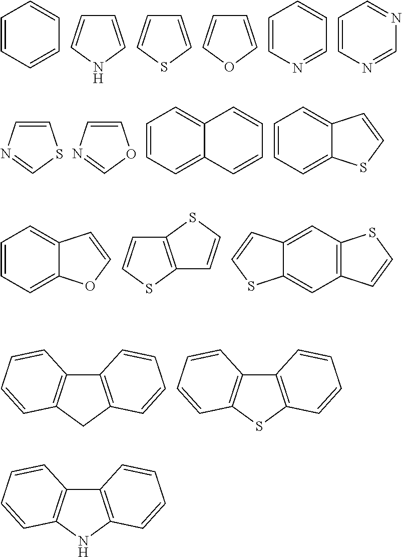

### Examples with 2 Ars

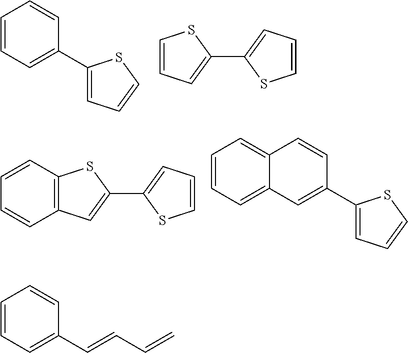

### Examples with 3 Ars

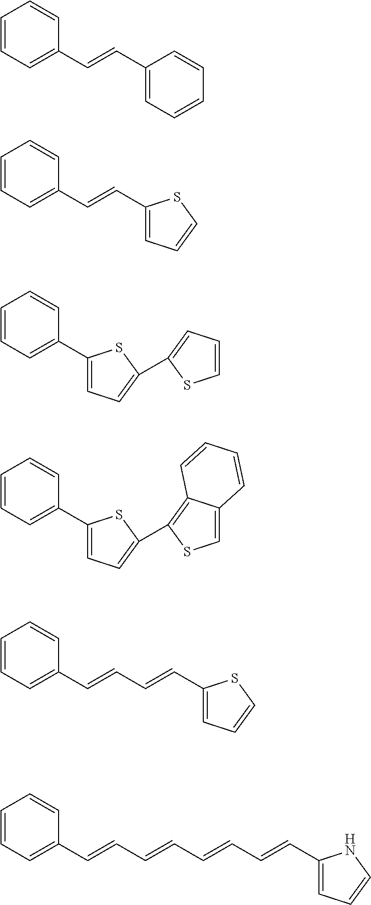

### Examples with 4 Ars

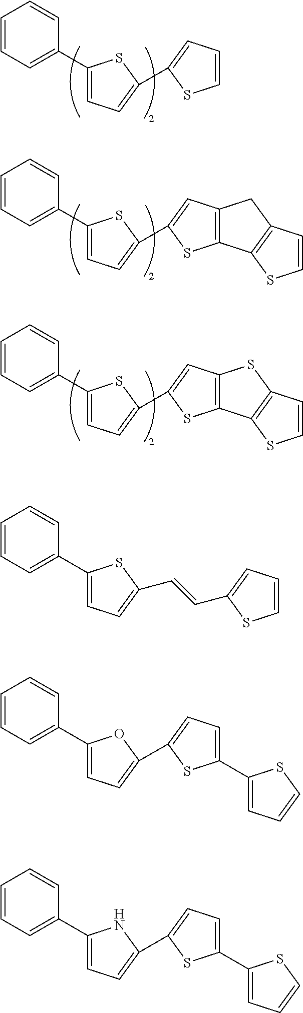

### Examples with 5 Ars Examples with 6 Ars

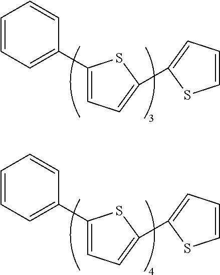

The hydrogen atom of the above aromatic ring-containing group and the unsaturated hydrocarbon group may be substituted with substituents. The substituents are not particularly limited, and examples thereof include alkyl groups of from C1 to C30 such as methyl groups, ethyl groups, propyl groups, isopropyl groups, tert-butyl groups, pentyl groups, hexyl groups, octyl groups, dodecyl groups, tridecyl groups, tetradecyl groups, pentadecyl groups, hexadecyl groups, heptadecyl groups, and octadecyl groups; cycloalkyl groups of from C3 to C30 such as cyclopentyl groups, and cyclohexyl groups; alkenyl groups of from C2 to 030 such as vinyl groups, and aryl groups; alkynyl groups of from C2 to C30 such as ethynyl groups, and propargyl groups, aryl groups of from C6 to C30 such as phenyl groups, tolyl groups, xylyl groups, and chlorophenyl groups; saturated heterocyclic groups of from C1 to C30 such as pyrrolidine groups, imidazolidine groups, morpholine groups, and oxazolidine groups; alkoxy groups of from C1 to C30 such as methoxy groups ethoxy groups, propyloxy groups, pentyloxy groups, hexyloxy groups, octyloxy groups, and dodecyloxy groups; cycloalkoxy groups of from C3 to C30 such as cyclopentyloxy groups, and cyclohexyloxy groups; aryloxy groups of from C6 to C30 such as phenoxy groups, and naphthyloxy groups; alkylthio groups of from C1 to C30 such as methylthio groups, ethylthio groups, propylthio groups, pentylthio groups, hexylthio groups, octylthio groups, and dodecylthio groups; cycloalkylthio groups of from C3 to C30 such as cyclopentylthio groups, and cyclohexylthio groups; arylthio groups of from C6 to C30 such as phenylthio groups, and naphthylthio groups; alkoxycarbonyl groups of from C2 to C30 such as methyloxycarbonyl groups, ethyloxycarbonyl groups, butyloxycarbonyl groups, octyloxycarbonyl groups, and dodecyloxycarbonyl groups; aryloxy carbonyl groups of from C7 to C30 such as phenyloxycarbonyl groups, and naphthyloxycarbonyl groups; sulfamoyl groups of from C1 to C30 such as aminosulfonyl groups, methylaminosulfonyl groups, dimethylaminosulfonyl groups, butylaminosulfonyl groups, hexylaminosulfonyl groups, cyclohexylaminosulfonyl groups, octylaminosulfonyl groups, dodecylaminosulfonyl groups, phenylaminosulfonyl groups, naphthylaminosulfonyl groups, and 2-pyridylaminosulfonyl groups; acyl groups of from C2 to C30 such as acetyl groups, ethylcarbonyl groups, propylcarbonyl groups, pentylcarbonyl groups, cyclohexylcarbonyl groups, octylcarbonyl groups, 2-ethylhexylcarbonyl groups, dodecylcarbonyl groups, phenylcarbonyl groups, naphthylcarbonyl groups, and pyridylcarbonyl groups; acyloxy groups of from C2 to C30 such as acetyloxy groups, ethylcarbonyloxy groups, butylcarbonyloxy groups, octylcarbonyloxy groups, dodecylcarbonyloxy groups, and phenylcarbonyloxy groups; amide groups of from C2 to C30 such as methylcarbonylamino groups, ethylcarbonylamino groups, propylcarbonylamino groups, pentylcarbonylamino groups, cyclohexylcarbonylamino groups, 2-ethylhexylcarbonylamino groups, octylcarbonylamino groups, dodecylcarbonylamino groups, phenylcarbonyl amino groups, and naphthylcarbonylamino groups; carbamoyl groups of from C1 to C30 such as aminocarbonyl groups, methylaminocarbonyl groups, dimethylaminocarbonyl groups, propylaminocarbonyl groups, pentylaminocarbonyl groups, cyclohexylaminocarbonyl groups, octylaminocarbonyl groups, 2-ethylhexylaminocarbonyl groups, dodecylaminocarbonyl groups, phenylaminocarbonyl groups, naphthylaminocarbonyl groups, and 2-pyridylaminocarbonyl groups; ureide groups of from C1 to C30 such as methylureide groups, ethylureide groups, pentylureide groups, cyclohexyureide groups, octylureide groups, dodecylureide groups, phenylureide groups, naphthylureide groups, and 2-pyridylaminoureide groups; sulfinyl groups of from C1 to C30 such as methylsulfinyl groups, ethylsulfinyl groups, butylsulfinyl groups, cyclohexylsulfinyl groups, 2-ethylhexylsulfinyl groups, dodecylsulfinyl groups, phenylsulfinyl groups, naphthylsulfinyl groups, and 2-pyridyl sulfinyl groups; alkylsulfonyl groups of from C1 to C30 such as methylsulfonyl groups, ethylsulfonyl groups, butylsulfonyl groups, cyclohexylsulfonyl groups, 2-ethylhexylsulfonyl groups, and dodecylsulfonyl groups; arylsulfonyl groups of from C6 to C30 or heteroarylsulfonyl groups of from C4 to C30 such as phenylsulfonyl groups, naphthylsulfonyl groups, and 2-pyridylsulfonyl groups; amino groups such as methylamino groups, ethylamino groups, dimethylamino groups, butylamino groups, cyclopentylamino groups, 2-ethylhexylamino groups, dodecylamino groups, anilino groups, naphthylamino groups, and 2-pyridylamino groups; halogen atoms such as fluorine atoms, chlorine atoms, and bromine atoms; fluorohydrocarbon groups of from C1 to C30 such as fluoromethyl groups, trifluoromethyl groups, pentafluoroethyl groups, and pentafluorophenyl groups; cyano groups; nitro groups; hydroxy groups; mercapto groups; and silyl groups of from C1 to C30 such as trimethylsilyl groups, triisopropylsilyl groups, triphenylsilyl groups, and phenyldiethylsilyl groups. Among these, alkyl groups of from C1 to C20, alkoxy groups of from C1 to C8, and halogen atoms are preferable. Furthermore, the substituents described above may be further substituted with the substituents described above. In addition, a plurality of the substituents may also bond with each other to form a ring.

A specific example is shown below in which the hydrogen atoms of the above described aromatic ring-containing groups and unsaturated hydrocarbon groups are substituted by a substituent.

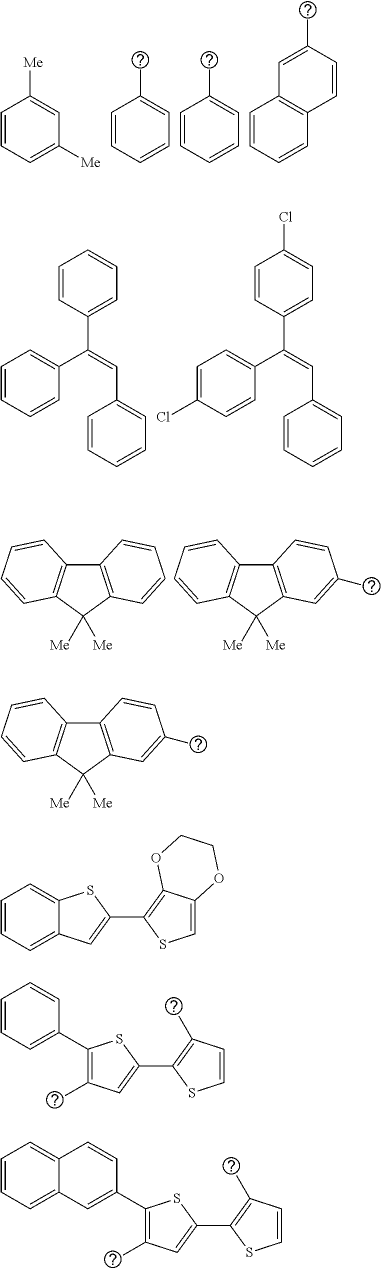

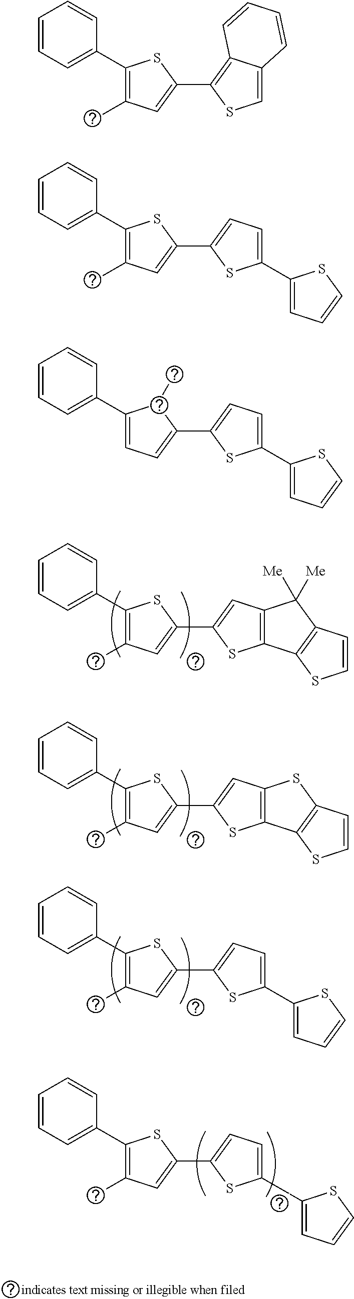

In the above Chemical Formula (1), n is an integer of from 1 to 9, preferably an integer of from 1 to 5, and when n is 2 or greater, the respective Ar₁s may be different from each other, m is an integer of from 1 to 9, preferably an integer of from 2 to 9, and when m is 2 or greater, the respective Ar₂s may be different from each other, 1 is an integer of from 1 to 5, and when 1 is 2 or greater, the respective Ar₃s may be different from each other, and in this case, m+n≧3 is satisfied, and when m=n, —(Ar₁)ₙ— and —(Ar₂)— are different from each other.

X is a monovalent substituent containing an acidic group. The sensitizing dye represented by the above Chemical Formula (1) may adsorb onto the above described semiconductor due to the acidic group which X has. In addition, by the Xs being the same, in other words, the sensitizing dye incorporating the same substituents, the adsorption power of the sensitizing dye onto the semiconductor increases and the durability of the photoelectric conversion element may be improved.

The above X is a monovalent substituent containing an acidic group, and in this case, examples of the acidic group within the substituent X include carboxy groups, sulfo groups (—SO₃H), and phosphonic acid groups [—PO(OH)₂]; in addition to salts of these and the like. Among these, it is preferable that the acidic group be a carboxy group. In addition, it is preferable that X further have an electron attracting group. Examples of the electron attracting group include cyano groups, nitro groups, fluoro groups, chloro groups, bromo groups, iodine groups, perfluoroalkyl groups (for example, trifluoromethyl groups), alkylsulfonyl groups, arylsulfonyl groups, perfluoroalkylsulfonyl groups, and perfluoroarylsulfonyl groups. Among these, having cyano groups, nitro groups, fluoro groups, and chloro groups is preferable, and having cyano groups and nitro groups is more preferable. In addition, it is preferable for the X to have a substructure. Examples of the substructure include rhodanine rings, dirhodanine rings, imidazolone rings, pyrazolone rings, pyrazoline rings, quinone rings, pyran rings, pyrazine rings, pyrimidine rings, imidazole rings, indole rings, benzothiazole rings, benzimidazole rings, benzoxazole rings, and thiadiazole rings. Among these, it is preferable to have rhodanine rings, dirhodanine rings, imidazolone rings, pyrazoline rings, quinone rings, and thiadiazole rings; and more preferable to have rhodanine rings, dirhodanine rings, imidazolone rings, and pyrazoline rings. These Xs may effectively inject photoelectrons into a semiconductor (in particular, an oxide semiconductor). In addition, in the substituent X, the acidic group and the electron attracting group and/or the substructure may be bonded via an atom such as an oxygen atom (O), a sulfur atom (S), a selenium atom (Se), or a tellurium atom (Te). Alternatively, the substituent X may hold a charge, particularly a positive charge, and in this case, may have a counter ion such as Cl⁻, Br⁻, I⁻, ClO₄⁻, NO₃⁻, SO₄²⁻, or H₂PO₄⁻.

A preferable structure of the substituent X will be exemplified below.

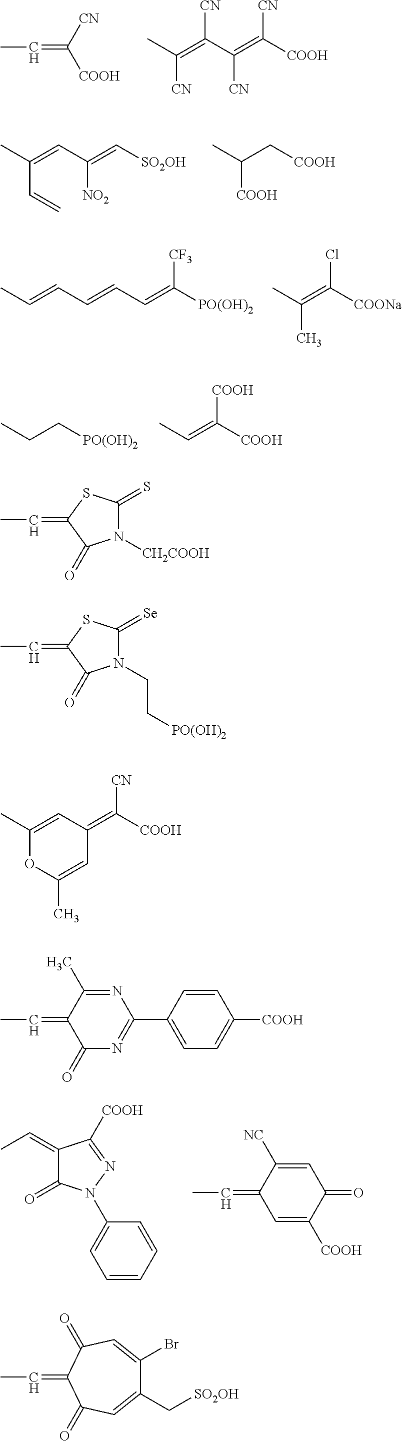

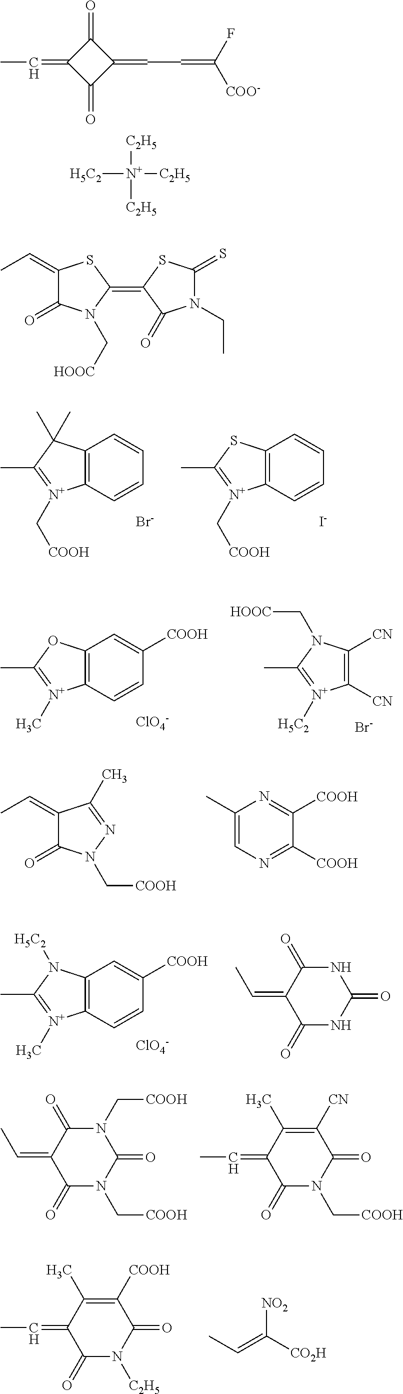

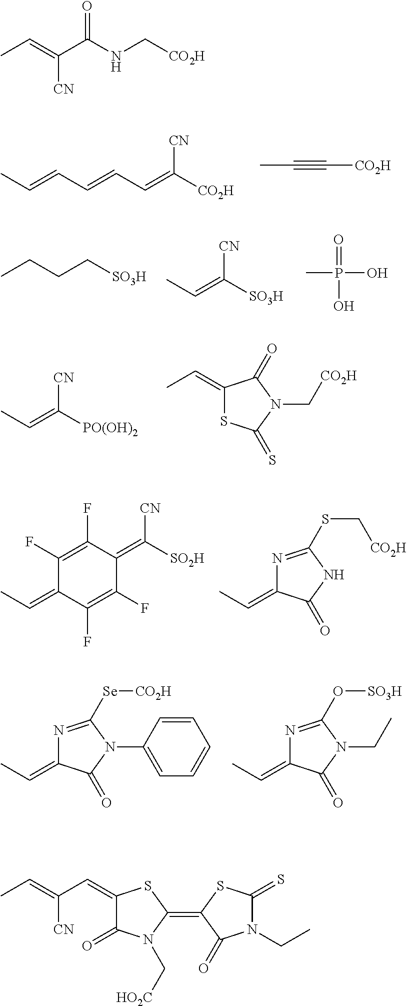

In addition, Y is a hydrogen atom or a monovalent substituent. The substituent is the same as the substituent which the hydrogen atom of the above described aromatic ring-containing groups and unsaturated hydrocarbon groups may be substituted by.

Specific examples of the compound represented by General Formula (1) are shown below, however, the present invention is not limited thereto.

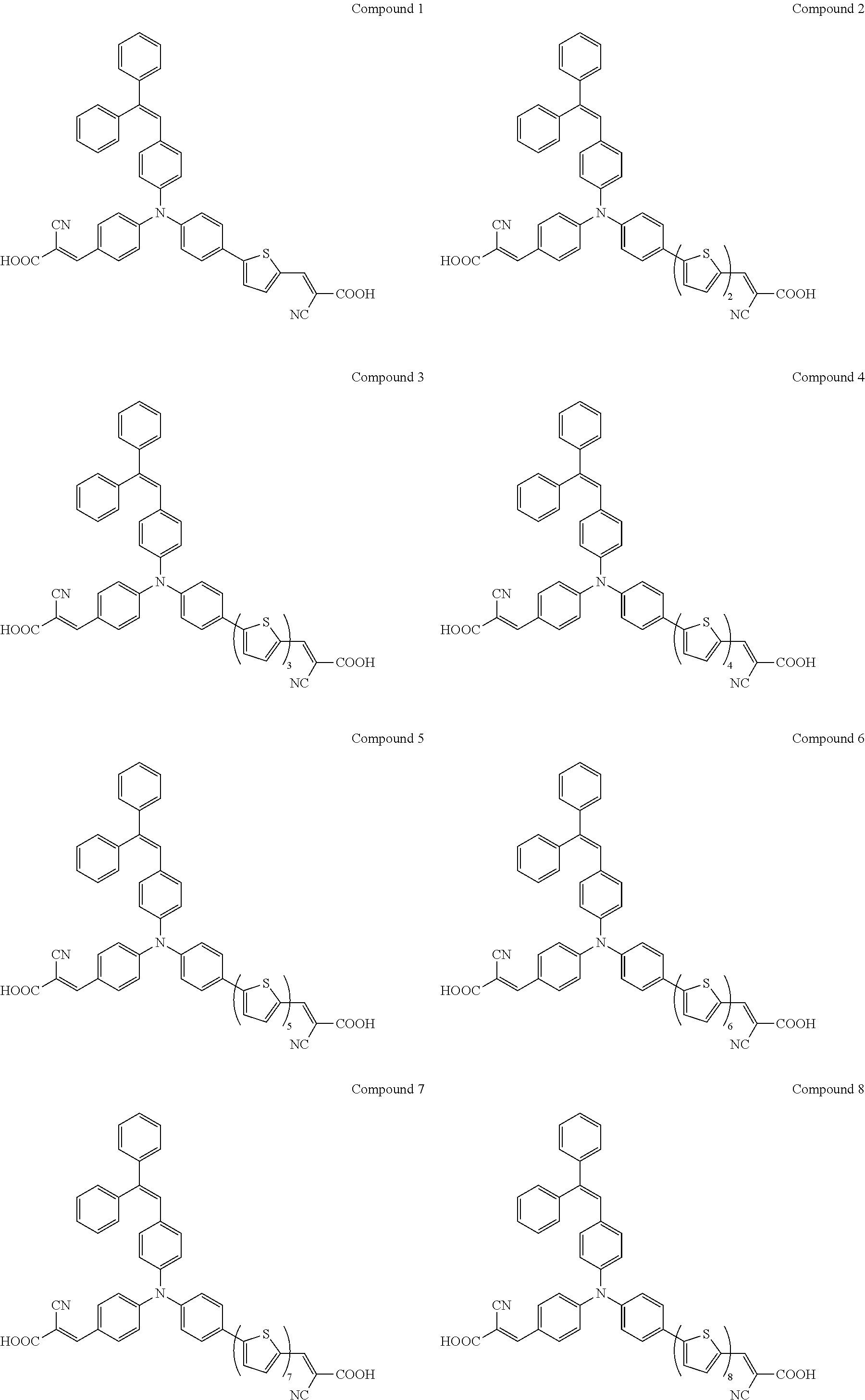

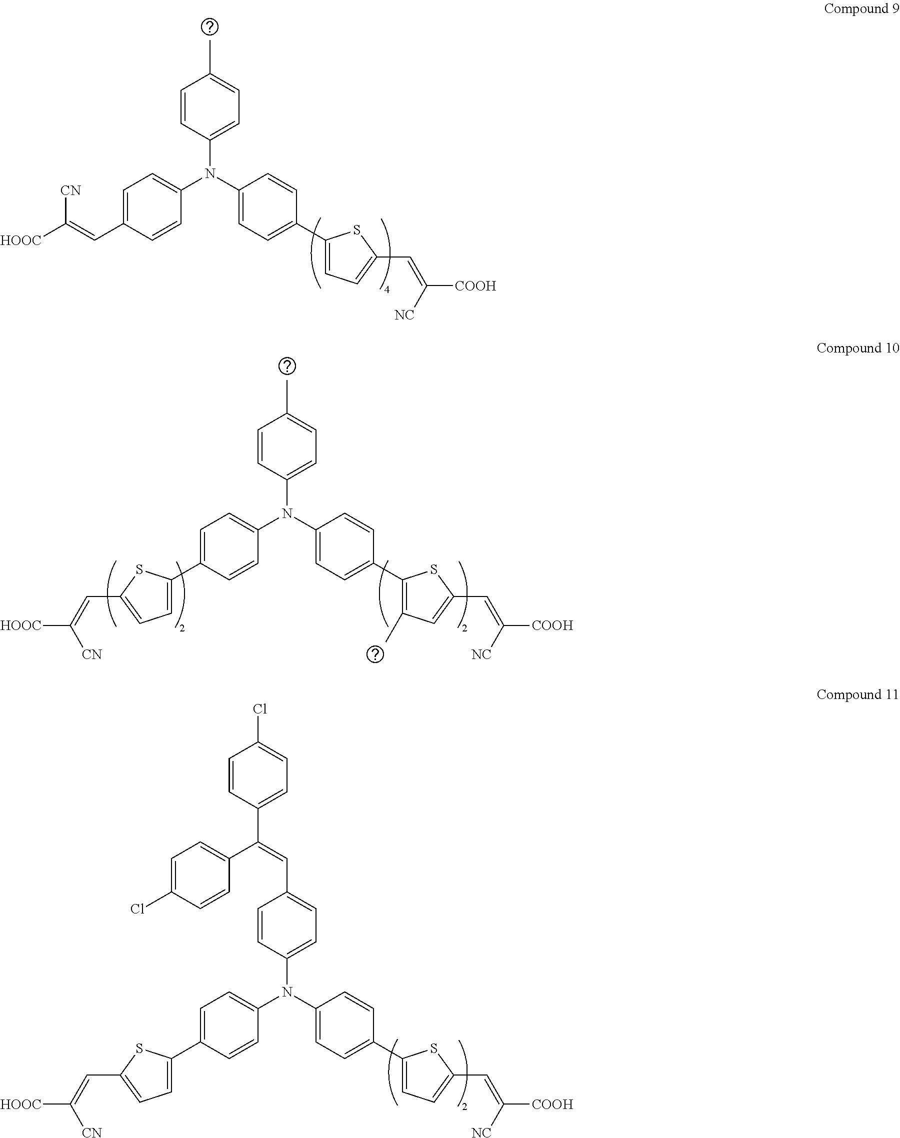

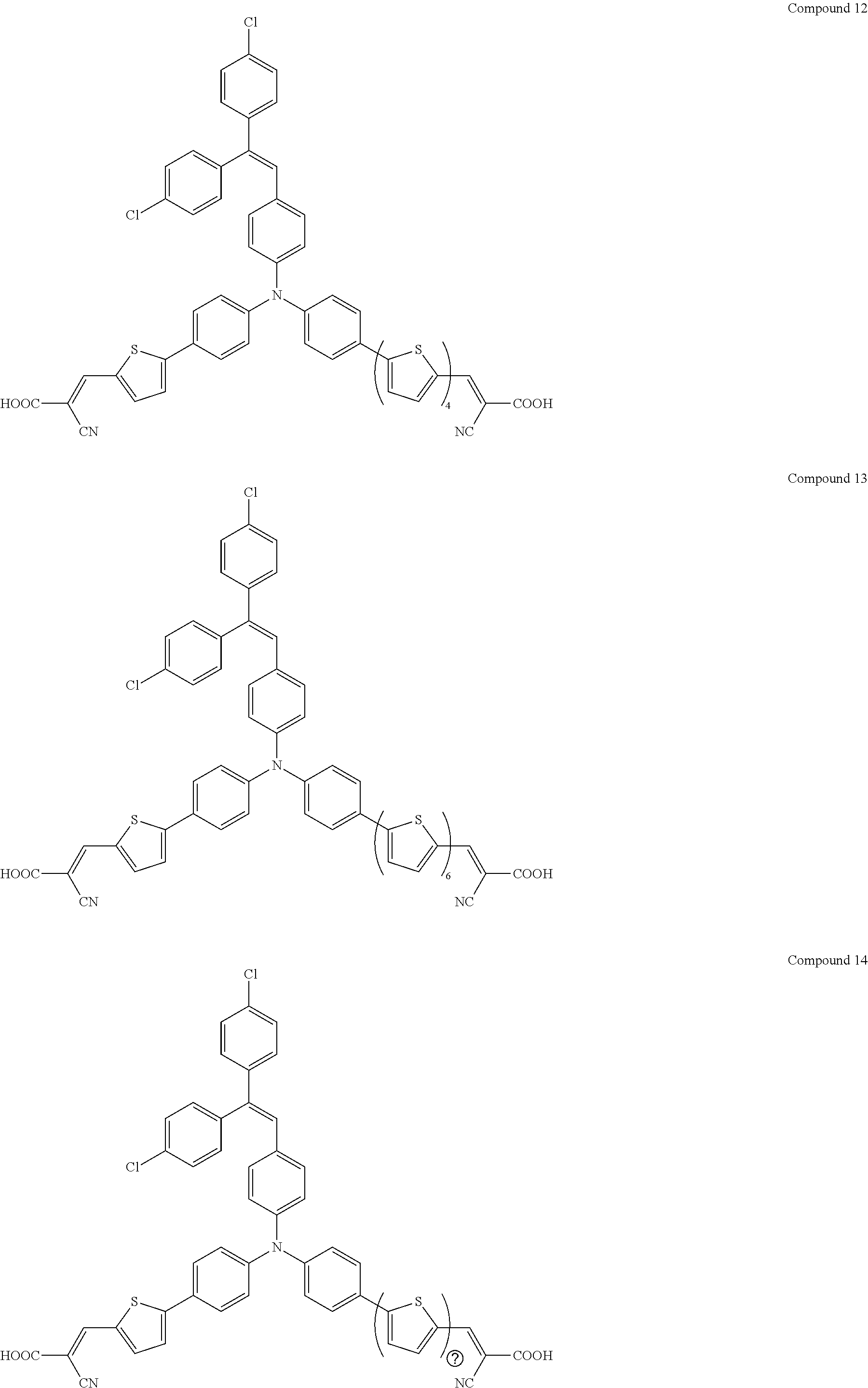

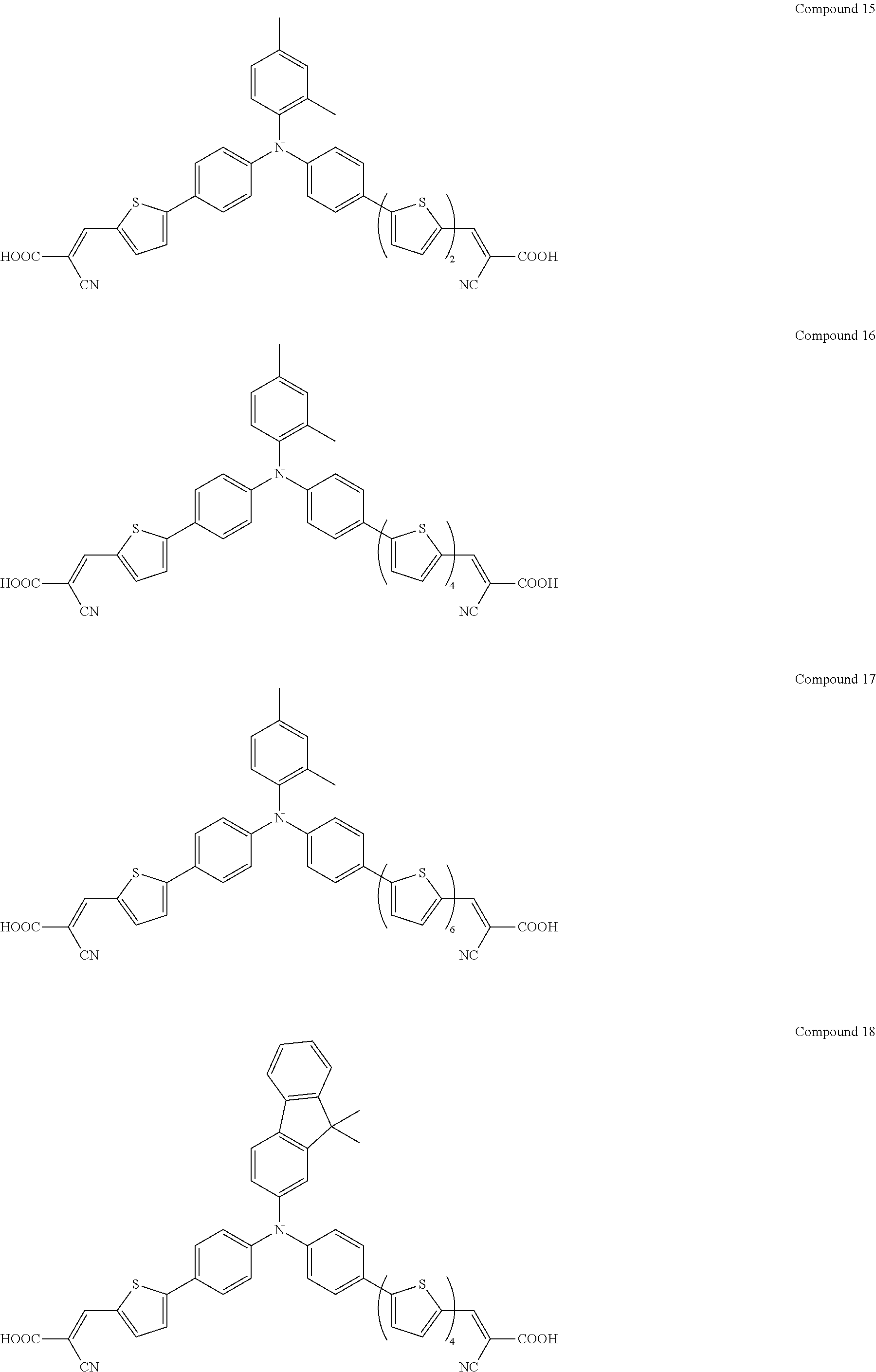

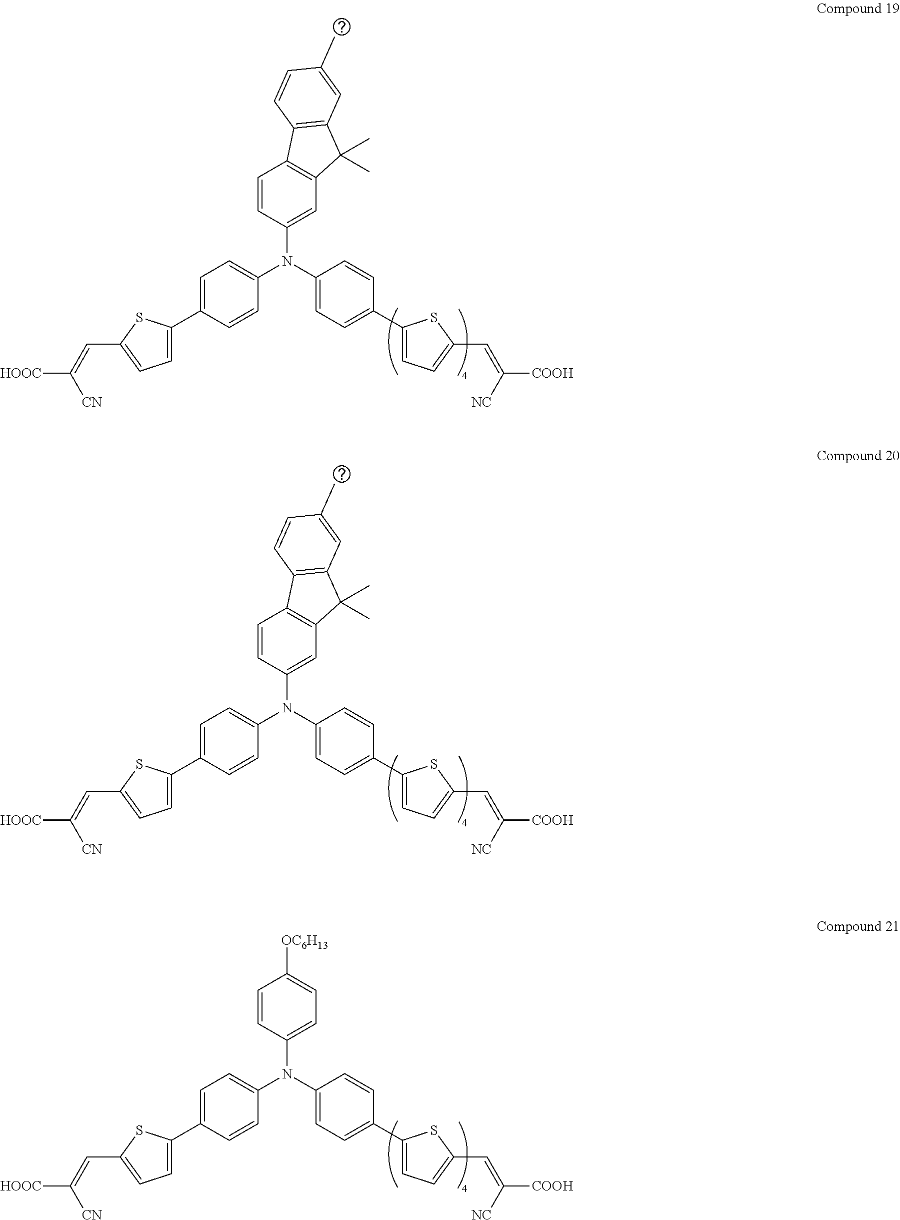

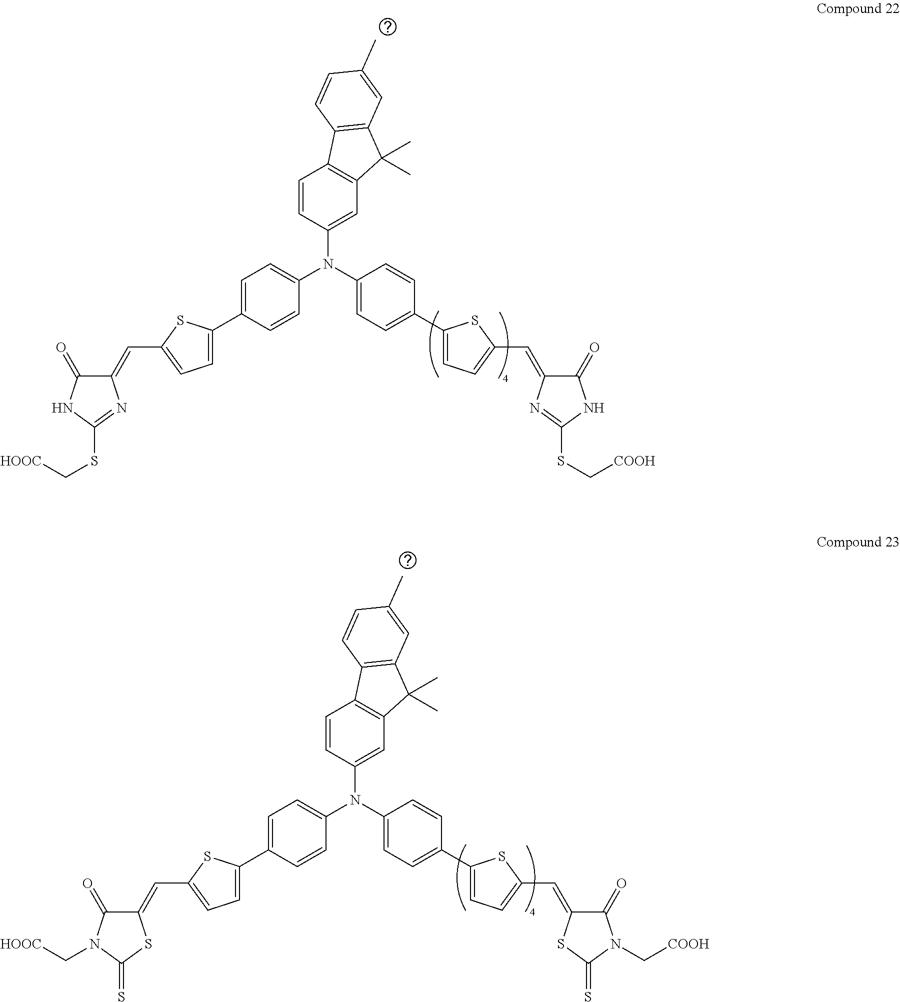

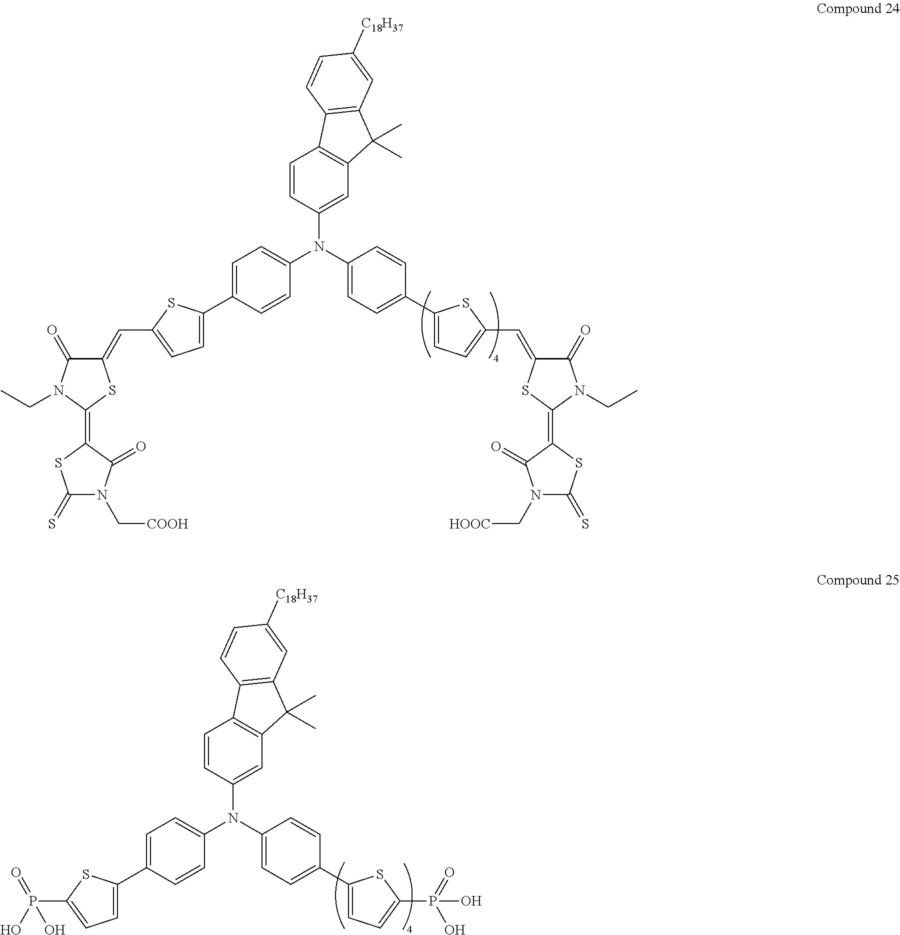

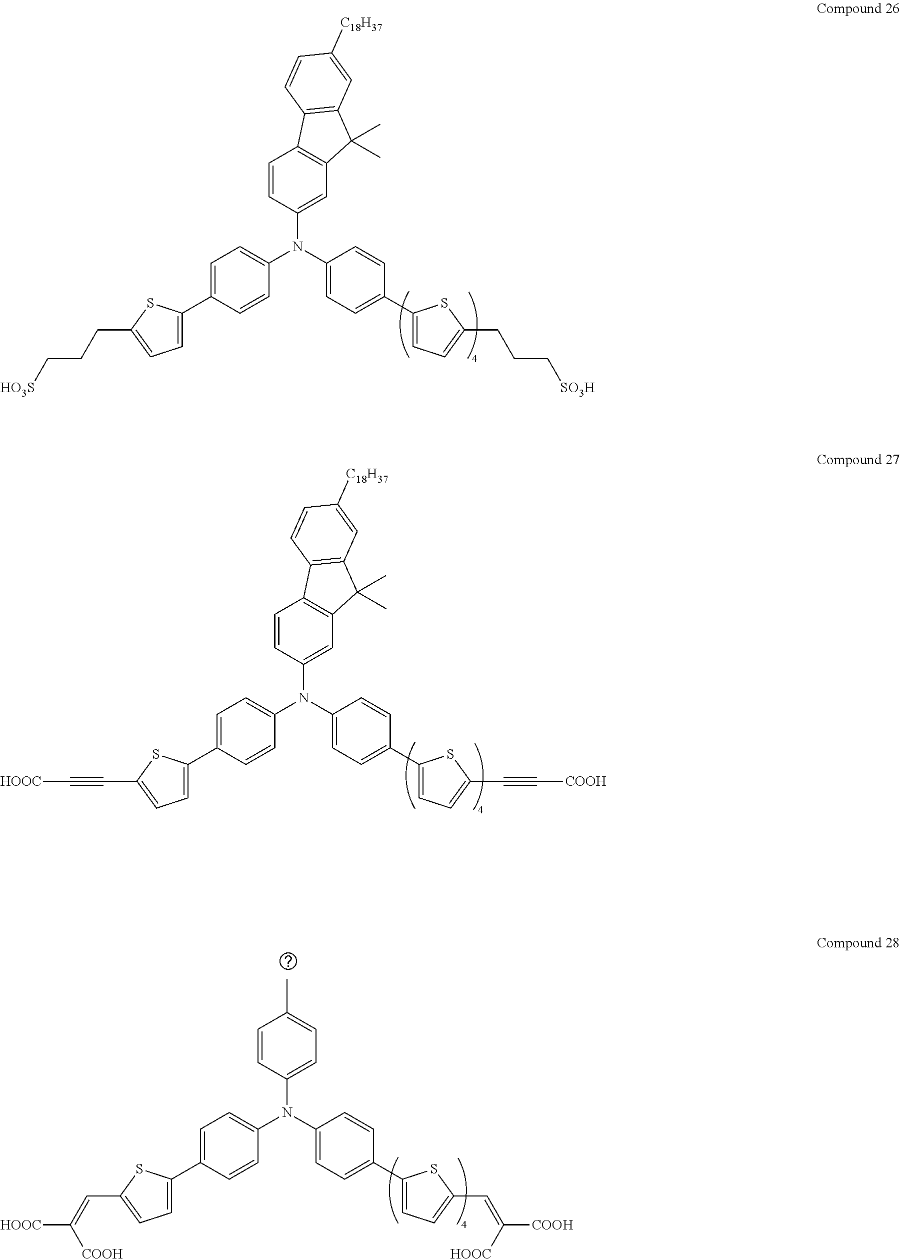

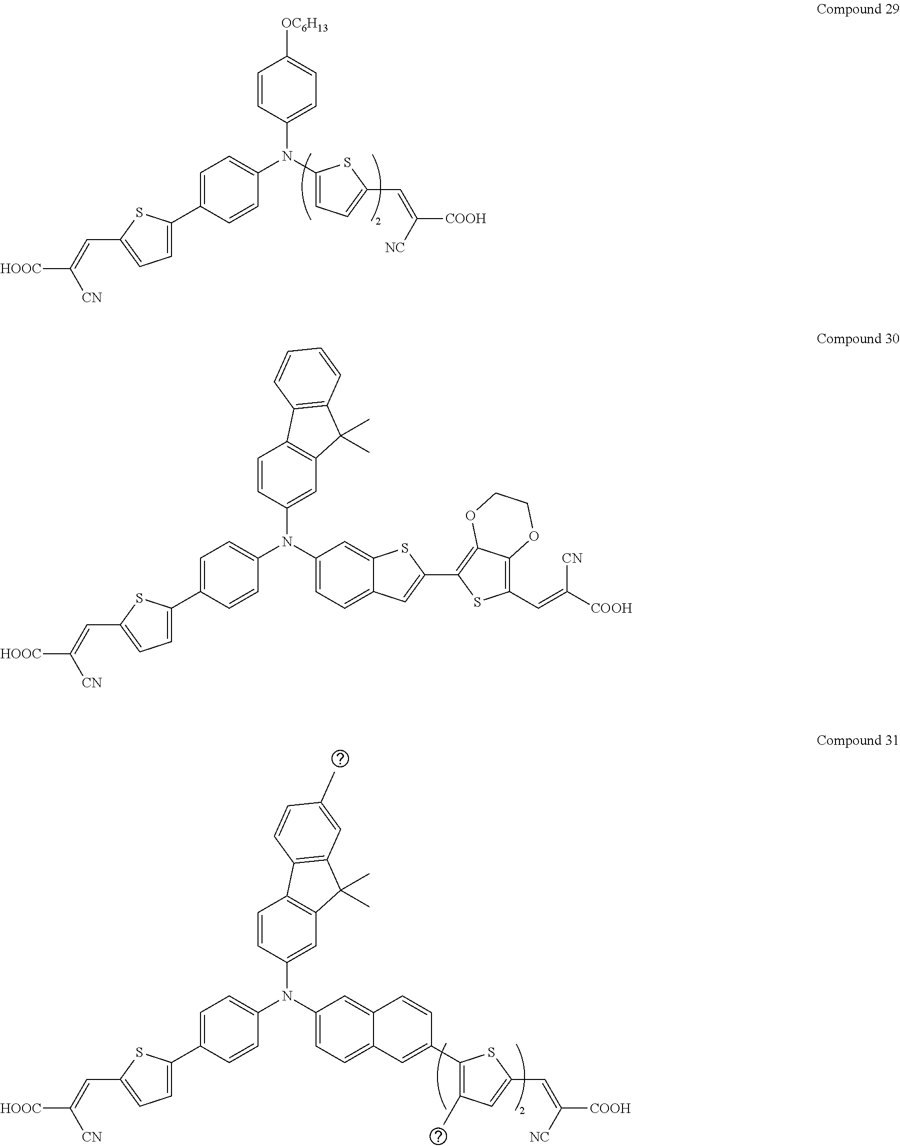

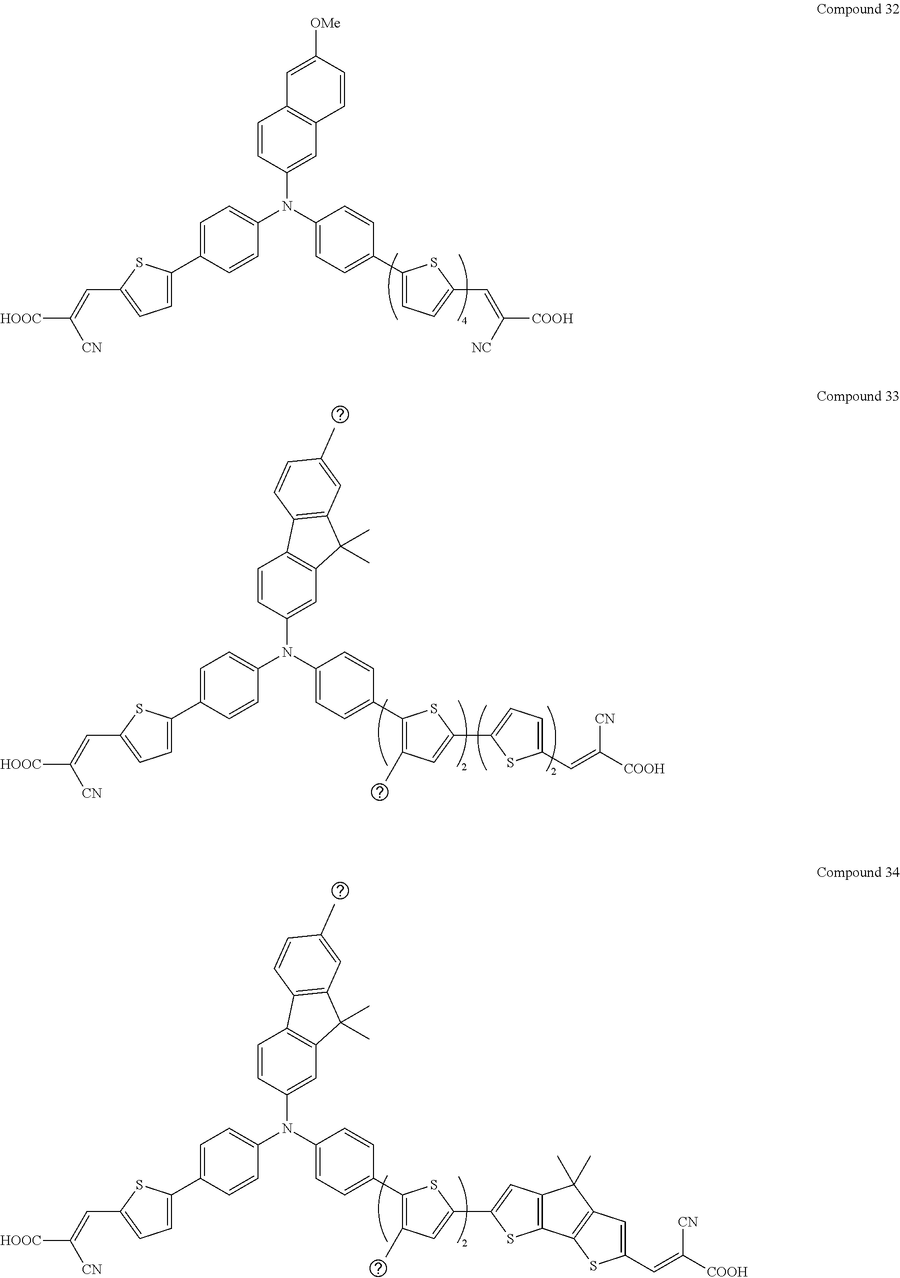

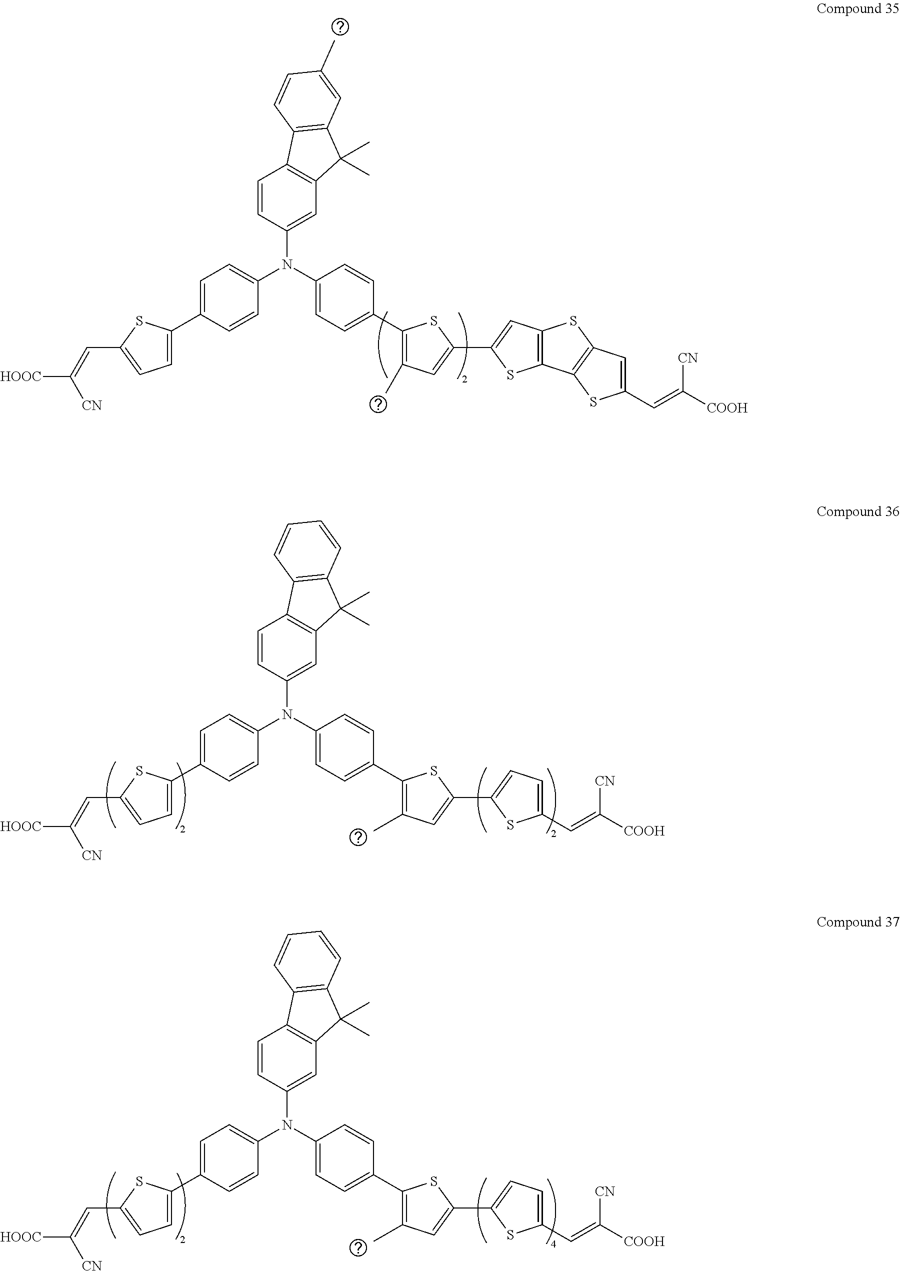

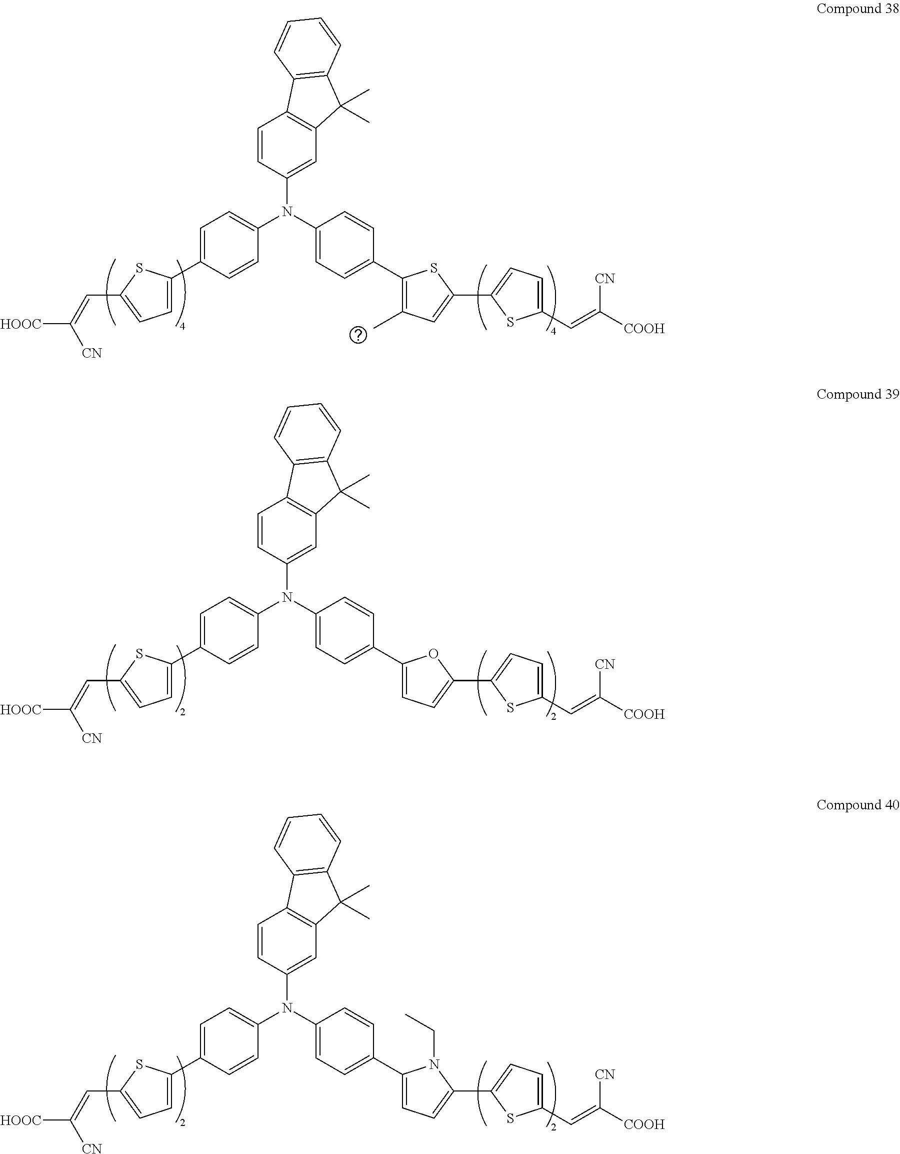

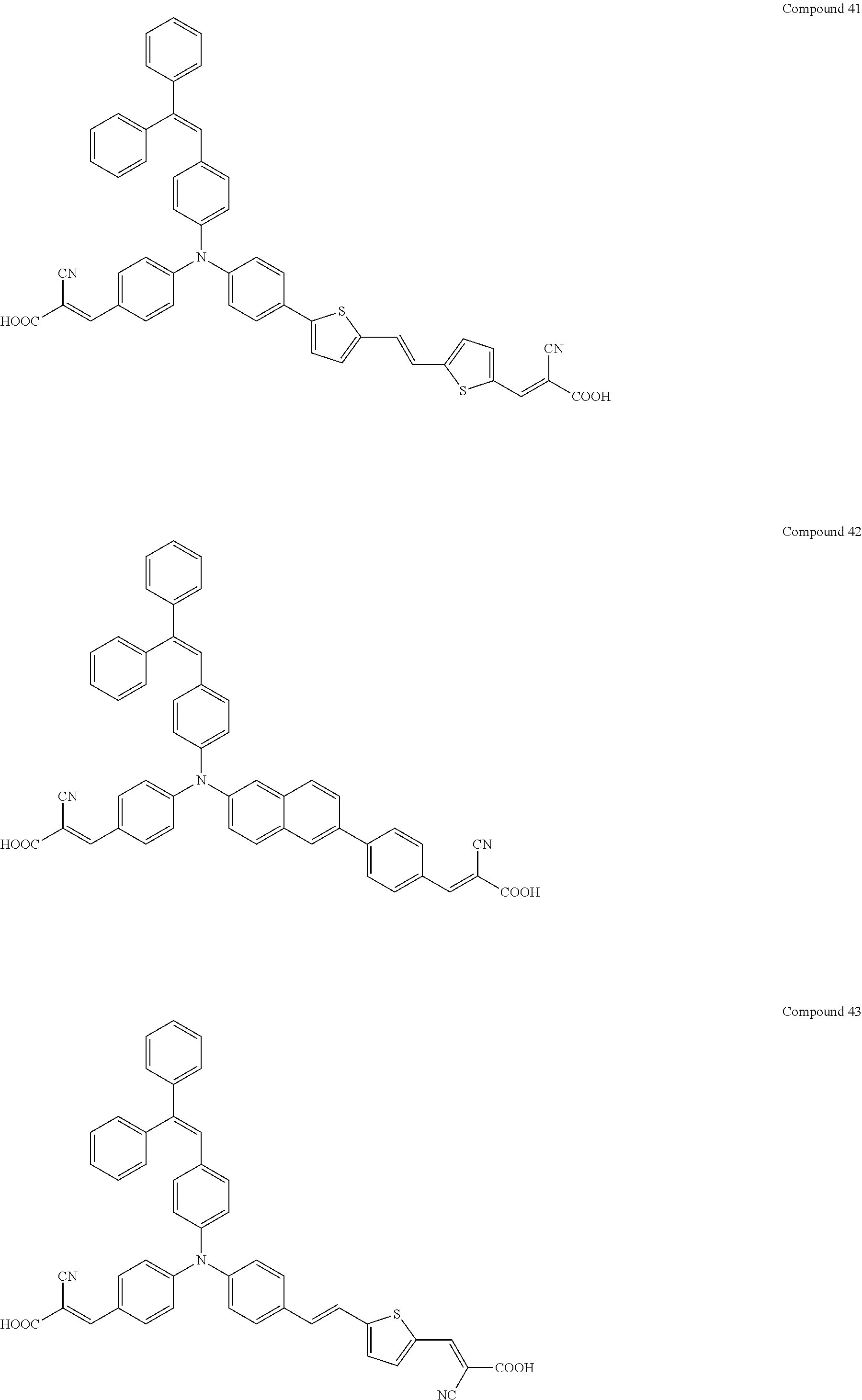

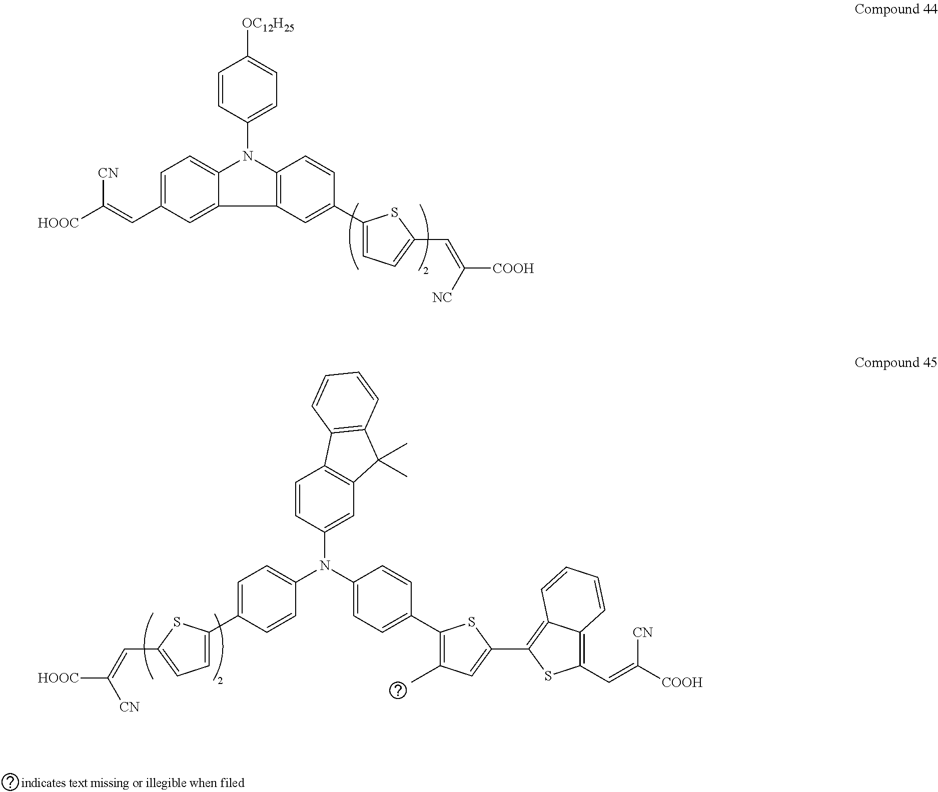

A person skilled in the art may synthesize the above compound by appropriately combining reactions which are all publicly known, for example, an electrophilic aromatic substitution reaction, an aromatic nucleophilic substitution reaction, a coupling reaction, a metathesis reaction, and the like. In addition, JP-A Nos. 7-5706, 7-5709 and the like may be referred to in relation to the synthesis of the above compound.

Furthermore, the compounds exemplified above all satisfy General Formula (1). As an example thereof, in compound 1, Ar₁ is a divalent aromatic ring-containing group derived from benzene, Ar₂ is a divalent aromatic ring-containing group derived from benzene and thiophene, Ar₃ is a divalent aromatic ring-containing group derived from benzene, and a divalent unsaturated hydrocarbon group derived from ethylene, and in this case, n is 1, m is 2, 1 is 3 (−(Ar₁)ₙ— and —(Ar₂)ₘ— differ from each other), m+n≧3 is satisfied, and X is a monovalent substituent containing a carboxy group, which is an acidic group, and a cyano group, which is an electron attracting group, and Y is a hydrogen atom. In addition, in compound 30, Ar₁ is a divalent aromatic ring-containing group derived from benzene and thiophene, Ar₂ is a divalent aromatic ring-containing group derived from thiophene having a substituent in which benzothiophene and two neighboring methoxy groups are bonded to each other to form a ring, Ar₃ is a divalent aromatic ring-containing group derived from fluorene having two methyl groups as substituents, and in this case, n is 2, m is 2, 1 is 1 (—(Ar₁))ₙ— and —(Ar)ₘ— differ from each other), m+n≧3 is satisfied, and X is a monovalent substituent containing a carboxy group, which is an acidic group, and a cyano group, which is an electron attracting group, and Y is a hydrogen atom.

Among the above compounds, in one embodiment of the present invention, it is preferable that at least one of the Ar₁, Ar₂, and Ar₃ in the sensitizing dye represented by the Chemical Formula (1) has at least one thiophene ring structure. Furthermore, it is preferable that the thiophene ring binds to the X or Y.

In addition, it is preferable that at least one of the Ar₁, Ar₂, and Ar₃ has at least one substituent selected from the group consisting of alkyl groups of from C1 to C20, alkoxy groups of from C1 to C8, and halogen atoms.

It is preferable from a viewpoint of solubility and durability that, among the above described compounds, the sensitizing dye represented by the Chemical Formula (1) be the aromatic group represented by the Chemical Formula (2) below.

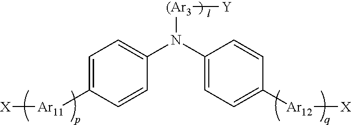

wherein, Ar₁₁ and Ar₁₂ are each independently a divalent aromatic ring-containing group or a divalent unsaturated hydrocarbon group,

p is an integer of from 0 to 8, and in this case, when p is 2 or greater, the respective Ar₁₁s may be different from each other, q is an integer of from 0 to 8, and in this case, when q is 2 or greater, the respective Ar₁₂s may be different from each other, p+q≧1 is satisfied, and when p=q, —(Ar₁₁)ₚ— and —(Ar₁₂)_{q}— are different from each other.

In one preferable embodiment of the present invention, at least one of the Ar₃, Ar₁₁, and Ar₁₂ has at least one thiophene ring structure. Furthermore, it is preferable that the thiophene ring binds to the X or Y.

In addition, in one embodiment of the present invention, at least one of the Ar₃, Ar₁₁, and Ar₁₂ has at least one substituent selected from the group consisting of alkyl groups of from C1 to C20, alkoxy groups of from C1 to C8, and halogen atoms.

### (Manufacturing Method of Photoelectric Conversion Layer)

Next, the manufacturing method of the photoelectric conversion layer will be described. The manufacturing method of the photoelectric conversion layer is broadly divided into (1) the forming of the semiconductor layer on the conductive support body, and (2) the sensitizing treatment of the semiconductor. In (1), when the material of the semiconductor is a particulate, the semiconductor layer may be formed using a method in which a dispersing liquid or a colloidal solution of the semiconductor (a semiconductor containing coating liquid) is coated or sprayed onto the conductive support body, a sol gel method in which a precursor of semiconductor fine particles is coated onto the conductive support body and condensation is performed after hydrolysis according to the moisture (for example, the moisture in an air atmosphere), and the like. It is preferable to fire the semiconductor layer obtained using the above two methods. In addition, when the material of the semiconductor is a film shape and is not held on the conductive support body, the semiconductor layer may be formed by bonding the semiconductor onto the conductive support body. Examples of the sensitizing treatment method of (2) include adsorption of the sensitizing dye to the semiconductor layer. In (1), when firing the semiconductor layer, after the firing, it is preferable to perform the sensitizing treatment with the sensitizing dye quickly, before the moisture is adsorbed onto the semiconductor.

A manufacturing method of the photoelectric conversion layer which may be used preferably in the present invention will be described below in detail.

### (1) Formation of Semiconductor Layer on Conductive Support Body

### (1-1) Preparation of Semiconductor Containing Coating Liquid

First, a coating liquid containing a semiconductor, preferably a fine powder of a semiconductor (a semiconductor containing coating liquid), is prepared. It is preferable that the primary particle diameter of the semiconductor fine powder be minute. The primary particle diameter is preferably from 1 nm to 5000 nm, and more preferably from 2 nm to 100 nm. The semiconductor containing coating liquid may be prepared by dispersing a semiconductor fine powder into a solvent, and the semiconductor fine powder dispersed in the solvent is dispersed in a primary particle shape. The concentration of the semiconductor fine powder in the solvent is preferably from 0.1% by weight to 70% by weight, and more preferably from 0.1% by weight to 30% by weight.

As solvents which may be used for the semiconductor containing coating liquid, as long as a semiconductor fine powder can be dispersed therein, there are no particular limitations, and water, an organic solvent, and a liquid mixture of water and an organic solvent may be used. Specific examples of the organic solvent include, for example, alcohols such as methanol, ethanol, and isopropyl alcohol; ketones such as methylethylketone, acetone, and acetylacetone; hydrocarbons such as hexane, and cyclohexane; and cellulose derivatives such as acetylcellulose, nitrocellulose, acetylbutylcellulose, ethylcellulose, and methylcellulose. Surfactants, acids (acetic acid, nitric acid, and the like), viscosity improvers (multivalent alcohols such as polyethylene glycol), and chelating agents (acetylacetone, and the like) may be added to the coating liquid as necessary.

### (1-2) Coating of Semiconductor Containing Coating Liquid

The semiconductor layer is formed by coating or spraying the semiconductor containing coating liquid which was prepared in (1-1) above onto the conductive support body and performing drying and the like. The coating is not particularly limited, and may be performed using a publicly known method such as the doctor blade method, the squeegee method, the spin coating method, the screen printing method, and the like. The semiconductor layer obtained by the above coating or spraying, and drying is formed from an aggregate of semiconductor fine particles, and the particle diameter of the fine particles corresponds to the primary particle diameter of the semiconductor fine powder which was used. Furthermore, the semiconductor containing coating liquid may contain two or more types of semiconductor material, and may also form a semiconductor layer of a layered structure by performing coating or spraying using two or more types of semiconductor material.

### (1-3) Firing Treatment of Semiconductor Layer

The semiconductor layer formed according to (1-2) above is preferably fired in the air atmosphere, or in an inert gas. By performing the firing, the bonding strength between, the semiconductor layer formed in (1-2) and the conductive support body, and the bonding strength of the semiconductor fine particles to each other may be increased, and the mechanical strength may be improved. The firing conditions are not particularly limited as long as a semiconductor layer having an intended true surface area or porosity may be formed. The firing temperature is not particularly limited, however, it is preferably 1000° C. or less, more preferably from 100° C. to 800° C., and particularly preferably from 200° C. to 600° C. In addition, when the substrate is plastic or the like and has inferior heat resistance, between the semiconductor fine particles and the substrate, and the semiconductor fine particles between each other may be adhered by pressurization, and the semiconductor layer may also be fired alone using microwaves. The firing time is not particularly limited, however, it is preferably from 10 seconds to 12 hours, more preferably from 1 minute to 240 minutes, and particularly preferably from 10 minutes to 120 minutes. In addition, the firing atmosphere is also not particularly limited, however, normally the firing step is performed in the air, or in an inert gas (for example, argon, helium, nitrogen, and the like). Furthermore, the above firing may be performed only once at a single temperature, and may also be performed two or more times repeatedly by changing the temperature or the time.

The structure of the fired semiconductor layer is not particularly limited, however, it is preferably a porous structure (a porous structure which has void) from the viewpoint of performing adsorption with the sensitizing dye effectively. Therefore, the porosity (D) of the semiconductor layer is preferably from 1 volume % to 90 volume %, more preferably from 10 volume % to 80 volume %, and particularly preferably from 20 volume % to 70 volume %. Furthermore, the porosity of the semiconductor layer means porosity with penetrability in the thickness direction of the dielectric, and may be measured by using a commercially available apparatus such as a mercury porosimeter (the Shimadzu Pore Sizer 9220-type). Furthermore, when the semiconductor layer is a porous structure film, it is preferable to manufacture the photoelectric conversion element so that the material which configures the hole transport layer is also present in this gap.

The film thickness of the fired semiconductor layer is not particularly limited, however, it is preferably 10 nm or greater, and more preferably from 500 nm to 30 μm.

The ratio of the true surface area to the apparent surface area of the obtained semiconductor layer may be controlled by the particle diameter and specific surface area of the semiconductor fine particles, and the firing temperature, and the like. In addition, with the obtained semiconductor layer, after firing, the surface area of the semiconductor particles and the purity of the vicinity of the semiconductor particles may be controlled to increase the electron injection efficiency from the dye to the semiconductor particles, due to performing chemical plating using titanium tetrachloride aqueous solution, or electrochemical plating treatment using a titanium trichloride aqueous solution, for example.

(2) Sensitizing Treatment of Semiconductor with Sensitizing Dye

The sensitizing treatment of the semiconductor by the sensitizing dye is performed by, for example, dissolving the sensitizing dye in a suitable solvent, and immersing a semiconductor layer, which has been thoroughly dried, in the solution for a long period of time. The sensitizing dye may be adsorbed onto the semiconductor by using the sensitizing treatment. In this case, when the semiconductor layer has a porous structure, preprocessing such as decompression processing and heat treatment are performed before the immersion, and it is preferable to remove bubbles from the film or moisture from the gap. The sensitizing dye may be adsorbed onto the inside of the semiconductor layer by the preprocessing. Furthermore, the sensitizing treatment is not limited to immersion of the semiconductor layer in the sensitizing dye containing solution, and other publicly known sensitizing treatment methods may also be appropriately applied.

The sensitizing treatment conditions are not particularly limited, however, it is preferable that the conditions are set so that the sensitizing dye may deeply penetrate the semiconductor layer and adsorption and the like may progress sufficiently. For example, from a viewpoint of preventing the decomposition of the sensitizing dye in the solution, and the adsorption of a decomposition product onto the semiconductor layer, the temperature of the sensitizing treatment is preferably from 5° C. to 100° C., and more preferably from 25° C. to 80° C. In addition, the time of the sensitizing treatment is preferably from 15 minutes to 20 hours, and more preferably from 3 hours to 24 hours. In particular, it is preferable to perform the sensitizing treatment for from 2 hours to 48 hours at room temperature (25° C.), especially from 3 hours to 24 hours is preferable, however, the sensitizing treatment time may also be suitably changed according to the set temperature. In addition, from a viewpoint of shortening the sensitizing treatment time and adsorbing to a deep portion of the semiconductor layer, the sensitizing treatment may also be performed under reduced pressure or vacuum.

The solvent used to dissolve the sensitizing dye is not particularly limited as long as it is able to dissolve the sensitizing dye and does not dissolve the semiconductor or react with the semiconductor. However, in order to prevent the sensitizing treatment such as the adsorption of the sensitizing dye from being impeded by the moisture and gas dissolved in the solvent penetrating the semiconductor film, it is preferable to refine the solvent by deaeration and distillation in advance. Examples of solvents which may be preferably used for dissolving the sensitizing dye include nitrile-based solvents such as acetonitrile; alcohol-based solvents such as methanol, ethanol, n-propanol, isopropyl alcohol, and tert-butyl alcohol; ketone-based solvents such as acetone, and methylethylketone; ether-based solvents such as diethyl ether, diisopropyl ether, tetrahydrofuran, and 1,4-dioxane; and halogen hydrocarbon solvents such as methylene chloride, and 1,1,2-trichloroethane. These solvents may be used either in isolation and may also be used in a combination of two or more types. Among these, it is preferable to use acetonitrile, methanol, ethanol, n-propanol, isopropyl alcohol, tert-butyl alcohol, acetone, methylethylketone, tetrahydrofuran, methylene chloride, and mixed solvents thereof, for example, acetonitrile/methanol mixed solvent, acetonitrile/ethanol mixed solvent, and acetonitrile/tert-butyl alcohol mixed solvent.

When performing the sensitizing treatment, the sensitizing dye may be used in isolation, and a plurality thereof may also be used together. In addition, the sensitizing dye may also be used mixed with another sensitizing dye (for example, the compounds disclosed in U.S. Pat. Nos. 4,684,537, 4,927,721, 5,084,365, 5,350,644, 5,463,057, 5,525,440, JP-A Nos, 7-249790, and 2000-150007), however, from a viewpoint of durability, it is preferable to use only the sensitizing dyes according to the present invention. When the photoelectric conversion element of the present invention is to be used as a solar battery as described below, it is preferable to use a mixture of two of more types of sensitizing dye which have different absorption wavelengths in order to effectively use sunlight by making the wavelength region of the photoelectric conversion as wide as possible. When two or more types of sensitizing dye are used, the sensitizing treatment method is not particularly limited, and the semiconductor layer may be immersed in a mixed solution of each sensitizing dye, and each sensitizing dye may be prepared as separate solutions into which the semiconductor layer is immersed sequentially.

In the obtained photoelectric conversion layer, the total supported amount of the sensitizing dye per 1 m² of the semiconductor layer is not particularly limited, however, it is preferably from 0.01 mmol to 100 mmol, more preferably from 0.1 mmol to 50 mmol, and particularly preferably from 0.5 mmol to 20 mmol.

### [Hole Transport Layer]

The hole transport layer has a function of supplying electrons to the sensitizing dye, which was oxidized by photo-excitation, to deoxidize the sensitizing dye, and transporting the hole, which occurs at the interface with the sensitizing dye, to the second electrode. The hole transport layer may fill not only the layer shaped portion formed on the porous semiconductor layer, but the inner portion of the gap of the porous semiconductor layer.

The hole transport layer may be configured with a redox electrolyte dispersoid or a p-type compound semiconductor or the like as the main component thereof.

As the redox electrolyte, an I⁻/I⁻ base, a Br⁻/Br₃⁻ base, and a quinone/hydroquinone base or the like may be used. The above redox electrolyte dispersoid may be obtained by using a publicly known method. For example, the I⁻/I₃⁻ based electrolyte may be obtained by mixing an iodide ion and iodine. The above redox electrolyte dispersoid is known as liquid electrolyte when used in a liquid form, solid polymer electrolyte when dispersed in a solid polymer at room temperature (25° C.), and gel electrolyte when dispersed in a gel substance. When the liquid electrolyte is used as the hole transport layer, an electrochemically inert solvent is used as the solvent thereof. As the solvent, for example, acetonitrile, propylene carbonate, ethylene carbonate, and the like are used. When a solid polymer electrolyte is used, the electrolyte disclosed in JP-A No. 2001-160427, and when a gel electrolyte is used, the electrolyte disclosed in “Surface Science” Vol. 21, Issue 5, pp. 288 to 293 may be referred to, respectively.

As the p-type compound, monomers of aromatic amine derivatives, pyridine derivatives, thiophene derivatives, pyrrole derivatives, stilbene derivatives, and the like, oligomers containing these monomers (in particular, dimers and trimers), and polymers may be used. Since the above monomers and oligomers have comparatively low molecular weights, the solubility thereof in solvents such as organic solvent is high, and coating onto the photoelectric conversion layer may be convenient. Meanwhile, for polymers, they are coated to the photoelectric conversion layer in a prepolymer form, and a method of performing polymerization on the photoelectric conversion layer to form a polymer may be convenient. There are no particular limitations to the method of the polymerization, for example, publicly known polymerization methods such as the method disclosed in JP-A No. 2000-106223 may be applied. Specifically, examples thereof include, an electrolytic polymerization method in which at least a working electrode and a counter electrode are provided, and a voltage is applied between both electrodes to make them react; a chemical polymerization method in which a polymerization catalyst is used; and a photopolymerization method in which light irradiation alone, or a combination of a polymerization catalyst, heating, electrolysis, and the like are used. Among these, it is preferable to use an electrolytic polymerization method. A photoelectric conversion element containing a p-type compound obtained by using electrolytic polymerization may have a particularly high open circuit voltage (Voc).

There are no particular limitations to the monomers and oligomers used as the above p-type compound, and a publicly known compound may be used. For example, examples of the aromatic amine derivatives include, for example, N,N,N′,N′-tetraphenyl-4,4′-diaminobiphenyl; N,N′-diphenyl-N,N′-bis(3-methylphenyl)-[1,1′-biphenyl]-4,4′-diamine (TPD); 2,2-bis(4-di-p-tolyl-aminophenyl) propane; 1,1-bis(4-di-p-tolyl-aminophenyl)cyclohexane; N,N,N′,N′-tetra-p-tolyl-4,4′-diaminobiphenyl; 1,1-bis(4-di-p-tolyl-aminophenyl)-4-phenyl-cyclohexane; bis(4-dimethylamino-2-methyl-phenyl)-phenylmethane; bis(4-di-p-tolyl-aminophenyl)phenylmethane; N,N′-diphenyl-N,N′-di(4-methoxyphenyl)-4,4-diaminobiphenyl; N,N,N′,N′-tetraphenyl-4,4′-diaminodiphenylether; 4,4′-bis diphenyl-amino)quadriphenyl; N,N,N-tri(p-tolyl)amine; 4-(di-p-tolylamino)-4′-[4-(di-p-tolylamino)styryl]stilbene; 4-N,N-diphenylamino-(2-diphenylvinyl)benzene; 3-methoxy-4′-N,N-diphenyl-aminostilbene; N-phenyl-carbazole; and 2,2′,7,7′-tetrakis(N,N′-di(4-methoxyphenl)amine)-9,9′-spirobifluorene (OMeTAD). In addition, the 4,4′-bis[N-(1-naphthyl)-N-phenylamino]biphenyl (NPD), which has two condensed aromatic rings within the molecule, disclosed in U.S. Pat. No. 5,061,569 the 4,4′, 4″-tris[N-(3-methyl-phenyl)-N-phenylamino]triphenyl amine (MTDATA), to which a triphenylamine unit is triple star-burst bonded, disclosed in JP-A No. 4-308688, or the like may be used. Among these, it is preferable to use aromatic amine derivative monomers which have excellent hole transportability, in particular, triphenyldiamine derivatives. Furthermore, a polymer material may also be used in which the above compound is introduced to the polymer chain, or is used as the main chain of the polymer.

There are no particular limitations to the polymers and prepolymers, which are the raw material of the polymers, used as the above p-type compound, and a publicly known compound may be used.

When a polymer is formed by electrolytic polymerization on the photoelectric conversion layer using a prepolymner, polymerization may be performed using a mixture containing, as well as the prepolymer, support electrolyte, a solvent, and, as necessary, an additive agent.

As the support electrolyte, an ionizable electrolyte is used, and is not limited to any specific electrolyte, however, an electrolyte which has a high solubility to the solvent and is not easily oxidized or reduced may be favorably used. Specifically, preferable examples thereof include salts such as lithium perchlorate (LiClO₄) lithium tetrafluoroborate, tetrabutyl ammonium perchlorate, Li[(CF₃SO₂)₂N], (n-C₄H₉)₄NBF₄, (n-C₄H₉)₄NPF₄, p-toluene sulfonate, and dodecylbenzene sulfonate. In addition, the polymer electrolyte disclosed in JP-A No. 2000-106223 (for example, PA-1 to PA-10 in the same gazette) may also be used as the support electrolyte. The above support electrolyte may be used either in isolation and may also be used in a combination of two or more types.

In addition, as the solvent, there are no particular limitations as long as the support electrolyte and the monomers or the polymers thereof may be dissolved, however, it is preferable to use an organic solvent with a comparatively wide potential window. Specific examples thereof include acetonitrile, tetrahydrofuran, propylene carbonate, dichloromethane, o-dichlorobenzene, dimethylformamide, and methylene chloride. In addition, the above solvents may also be used as a mixed solvent by adding water or other organic solvents thereto as necessary. The above solvents may be used either in isolation and may also be used in a combination of two or more types.

The electrolytic polymerization is, more specifically, performed by immersing the substrate forming the photoelectric conversion layer in an electrolytic polymerization solution containing a prepolymer or the like, using the photoelectric conversion layer as a working electrode, a platinum wire, a platinum plate, or the like as a counter electrode, and Ag/AgCl, Ag/AgNO₃, or the like as a reference electrode, and performing direct current electrolysis. There are no particular limitations to the concentration of the monomer or the polymer in the electrolytic polymerization solution, however, the concentration is preferably from 0.1 mmol/L to 1000 mmol/L, more preferably from 1 mmol/L to 100 mmol/L, and particularly preferably from mmol/L to 20 mmol/L. In addition, the concentration of the support electrolyte is preferably from 0.01 mol/L to 10 mol/L, and more preferably from 0.1 mol/L to 2 mol/L. In addition, the impressed current density is preferably from 0.01 μA/cm² to 1000 μA/cm², and more preferably from 1 μA/cm² to 500 μA/cm². The hold voltage is preferably from −0.50 V to +0.20 V, and more preferably from −0.30 V to 0.00 V. The temperature range of the electrolytic polymerization solution is preferably set to a range in which the solvent does not solidify or bump, which is generally from −30° C. to 80° C. In addition, a photopolymerization method, in which light is irradiated to perform polymerization, may also be used in combination with the electrolytic polymerization. The wavelength of light to irradiate is preferably from 350 nm to 80 nm. Furthermore, it is preferable to use a xenon lamp as the light source. In addition, the strength of the light is preferably from 1 mW/cm² to 100 mW/cm², and more preferably from 1 mW cm² to 50 mW cm². The polymer layer may be formed accurately on the surface of the photoelectric conversion layer (semiconductor layer) by performing electrolytic polymerization under the irradiation of light in this manner. According to the above method, the conditions of the electrolytic voltage, the electrolytic current, the electrolysis time, the temperature, and the like further depend on the material used, and may be selected appropriately according to the intended film thickness.

It is difficult to ascertain the degree of polymerization of the polymer from a polymer obtained by electrolytic polymerization. However, since the solvent solubility of the hole transport layer, which was formed after the polymerization, greatly decreases, it may be determined, from the solubility, as to whether a polymer has been formed or not by immersing the hole transport layer in a tetrahydrofuran (THF) in which it is possible to dissolve a prepolymer. Specifically, put 10 mg of a compound (polymer) into a 25 mL sample bottle, add 10 ml of THF, and when this is irradiated for 5 minutes with ultrasonic waves (25 kHz, 150 W, Ultrasonic Engineering Co. Ltd., COLLECTOR CURRENT 1.5 A, manufactured by Ultrasonic Engineering Co., Ltd. 150), in a case where the dissolved compound is 5 mg or less, it is determined to be polymerized.

Meanwhile, when a polymer is formed by chemical polymerization on the photoelectric conversion layer using a prepolymer, polymerization may be performed using a mixture containing, as well as the prepolymer, a polymerization catalyst, a solvent, and, as necessary, an additive agent such as a polymerization rate regulator.

The polymerization catalyst is not particularly limited, however, examples thereof include iron chloride (III), tris-p-toluene sulfonic acid iron (III), p-dodecylbenzene sulfonic acid iron (III), methanesulfonic acid iron (III), p-ethylbenzene sulfonic acid iron (III), naphthalenesulfonic acid iron (III), and hydrates thereof.

In addition, the polymerization rate regulator has a weak complexing agent in relation to the ferric ions in the polymerization catalyst, and is not particularly limited as long as the polymerization rate is reduced so that a film may be formed. For example, when the polymerization catalyst is an iron chloride (III) and the hydrate thereof, an aromatic oxysulfonic acid such as 5-sulfosalicylic acid may be used. In addition, when the polymerization catalyst is tris-p-toluene sulfonic acid iron (III), p-dodecylbenzene sulfonic acid iron (III), methanesulfonic acid iron (III), p-ethylbenzene sulfonic acid iron (III), naphthalenesulfonic acid iron (III), and hydrates thereof, imidazol and the like may be used.

The reaction conditions of the above chemical polymerization differ depending on the type, proportion, and concentration of prepolymer, polymerization catalyst, and polymerization rate regulator used, and the thickness of the liquid film at the coated stage, and the intended polymerization rate, however, as favorable polymerization conditions, when heating in an air atmosphere, it is preferable that the heating temperature be from 25° C. to 120° C., and the heating time be from 1 minute to 24 hours.

It is preferable to perform the polymerization such as the above described electrolytic polymerization and chemical polymerization on the photoelectric conversion layer, however, the hole transport layer may also be formed by polymerizing the prepolymer in advance and coating the photoelectric conversion layer with the obtained polymer. There are no particular limitations to the coating method, and a publicly known coating method may be used in the same manner, or appropriately modified. Specifically, various coating methods such as dipping, dropping, doctor blade, spin coating, brush application, spray coating, roll coating, air knife coating, curtain coating, wire bar coating, gravure coating, and extrusion coating used in the hopper disclosed in U.S. Pat. No. 2,681,294, and the multilayer simultaneous coating method disclosed in U.S. Pat. Nos. 2,761,418, 3,508,947, and 2761791, may be used. In addition, such a coating operation may also be performed repeatedly to perform laminating. There are no particular limitations to the number of coatings in this case, and this may be appropriately selected according to the intended thickness of the hole transport layer. In this case, examples of solvents which may be used include organic solvents such as polar solvents such as tetrahydrofuran (THF), butylene oxide, chloroform, cyclohexanone, chlorobenzene, acetone, and various alcohols; and aprotic solvents such as dimethylformamide (DMF), acetonitrile, dimethoxyethane, dimethylsulfoxide, and hexamethylphosphoric triamide. The above solvents may be used either in isolation and may also be used in the form of a combination of two or more types.

Various types of additive agent may be added to the hole transport layer as necessary, for example, acceptor doping agents, such as N(PhEr)₃SbCl₆, NOPF₆, SbCl₅, I₂, Br₂, HClO₄, (n-C₄H₉)₄ClO₄, trifluoroacetic acid, 4-dodecylbenzenesulfonate, 1-naphthalenesulfonate, FeCl₃, AuCl₃, NOSbF₆, AsF₅, NOBF₄, LiBF₄, H₃ [PMo₁₂O₄₀], and 7,7,8,8-tetracyanoquinodimethane (TCNQ), binder resin in which holes are not easily trapped, and coating modifiers such as a leveling agent. These additive agents may be used either in isolation and may also be used in a combination of two or more types.

It is preferable that the material contained in the hole transport layer have a large band gap in order to not impede the light absorption of the sensitizing dye. Specifically, it is preferable to have a band gap of 2 eV or greater, and more preferable to have a band gap of 2.5 eV or greater. In addition, it is preferable that the hole transport layer have a low ionization potential in order to reduce the sensitization dye hole. The value of the ionization potential differs according to the sensitizing dye applied, however, normally, from 4.5 eV to 5.5 eV is preferable, and from 4.7 eV to 5.3 eV is more preferable.

### [Second Electrode]

The second electrode is arranged in contact with the hole transport layer and may be configured by an arbitrary conductive material. Even an insulative substance may be used as lone as a conductive substance layer is provided on the side facing the hole transport layer. It is preferable that the second electrode have good contact with the hole transport layer from a viewpoint of reducing the electrical resistance of the element, and the like. In addition, it is preferable that the second electrode have a small work function difference with the hole transport layer and be chemically stable. Such a material is not particularly limited, however, examples thereof include metallic thin films such as gold, silver, copper, aluminium, platinum, chrome, rhodium, ruthenium, magnesium, and indium; and organic conductors such as carbon, carbon black, conductive polymers, and conductive metallic oxides (indium-tin complex oxides, tin oxide doped with fluorine, and the like). The material is preferably a metallic thin film such as gold. In addition, the thickness of the second electrode is not particularly limited, however, it is preferably from 10 nm to 1000 nm. In addition, the surface resistance value of the second electrode is not particularly limited, however, it is preferably the lowest possible value. Specifically, the surface resistance value is preferably 80 Ω/square or less, and more preferably 20 Ω/square or less.

When the photoelectric conversion element which has a configuration as described above is irradiated with light from the outside of the substrate, the sensitizing dye supported in the semiconductor layer of the photoelectric conversion layer inside the element is excited and releases electrons. The excited electrons are injected into the semiconductor and move to the first electrode. The electrons which moved to the first electrode move to the second electrode through an external circuit, and are supplied to the hole transport layer. Also, the sensitizing dye which (emitted electrons and) was oxidized accepts electrons from the hole transport layer, returning to a ground state. Light is converted into electricity by repeating such a cycle.

In the photoelectric conversion element according to the present invention, the sensitizing dye exhibits a wide absorption peak including visible light of sunlight by —(Ar₁)ₙ— and —(Ar₂)ₘ— being different from one another in Chemical Formula (1) As a result, the photoelectric conversion efficiency in relation to sunlight may be improved. In addition, the durability of the photoelectric conversion element may be improved due to being able to stabilize the adsorption of the sensitizing dye onto the semiconductor by incorporating a monovalent substituent containing the same acidic group in the molecule of the sensitizing dye. Therefore, the photoelectric conversion element according to the present invention has excellent photoelectric conversion efficiency, and high durability.

### <Solar Battery>

The photoelectric conversion element according to the present invention may be used particularly favorably in a solar battery. Therefore, the present invention also provides a solar battery characterized by having the photoelectric conversion element according to the present invention.

The photoelectric conversion element according to the present invention may be used as a dye sensitization-type solar battery (cell). In other words, the solar battery according to the present invention, for example, has a plurality of solar battery cells (the photoelectric conversion element according to the present invention) which are electrically connected via an interconnector, a pair of protective members which interpose the solar battery cells, and a sealing resin which fills the gap between the pair of protective members and the plurality of solar batteries. One of the pair of protection members is the previously described substrate of the photoelectric conversion element. Both of the pair of protection members may be transparent, and one thereof only may also be transparent.

Examples of the configuration of the solar battery according to the present invention include a Z-type module and a W-type module. The Z-type module has a structure in which, among the facing pair of protection members, a porous semiconductor layer which supports a plurality of dyes is formed on the protection member of one, a plurality of hole transport layers are formed on the substrate of the other, and these are bonded together. The W-type module has a structure in which a porous semiconductor layer which supports a dye and a hole transport layer laminated body are alternately formed for each of the respective protection members, and the cells are bonded together so as to alternate.

When sunlight or an electromagnetic wave equivalent to sunlight is irradiated to the solar battery according to the present invention, the sensitizing dye supported on the semiconductor absorbs the light or electromagnetic wave which was irradiated thereto and is excited. The electrons which were generated by the excitation move to the semiconductor, then move to the second electrode via a conductive support body and an external load, and are supplied to the hole transport material of the hole transport layer. Meanwhile, the sensitizing dye, the electrons of which were moved to the semiconductor, is an oxide, however, the sensitizing dye is reduced and returned to its original state by being supplied electrons from the second electrode thereto via a polymer of the hole transport layer, at the same time the polymer of the hole transport layer is oxidized and returns again to a state in which it may be reduced by a supply of electrons from the second electrode. Electrons flow in this manner, and a solar battery using the photoelectric conversion element according to the present invention may be configured.

### EXAMPLES

Hereinafter, the present invention will be described using Examples, however, the present invention is not limited thereto.

### Synthesis Example 1

### Synthesis of Compound 15

Compound 15 was synthesized according to the scheme below.

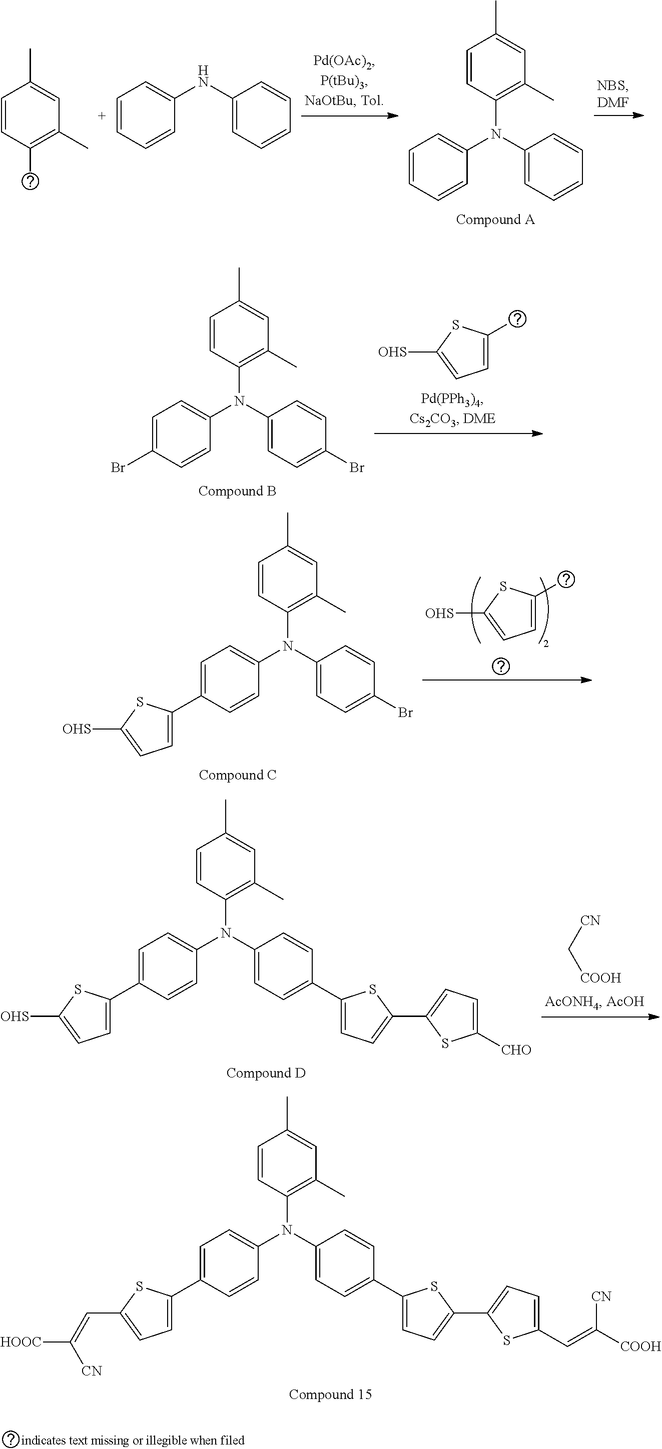

After adding 0 equivalent of tert-butylphosphine to 0.1 equivalent of palladium acetate toluene solution and stirring this at 80° C., the mixture was cooled to room temperature. To the solution, 1 equivalent of 2-bromo-m-xylene toluene solution, 1 equivalent of diphenylamine, and 2 equivalent of tert-butoxysodium were added. After stirring for 6 hours at 7000, water was added to the reaction liquid. The reaction liquid was extracted using ethyl acetate, washed using water, and dried using magnesium sulfate. The solvent of the obtained extract was distilled using a rotary evaporator, refined using silica gel column chromatography, and compound A was obtained.

The obtained compound A was dissolved in DMF, and 3 equivalent of N-bromosuccinimide was added thereto. After stirring for 5 hours at 60° C., water was added to the reaction liquid. The precipitate of the reaction liquid was filtered out, washed using water, and a solid compound B was obtained.

The obtained compound B was dissolved in dimethoxyethane, and 1.05 equivalent of 5-formyl-2-thiophene boronic acid, 0.05 equivalent of tetrakis triphenylphosphine palladium, and 2 equivalent of cesium carbonate were added thereto. After stirring for 11 hours at 80° C., water was added to the reaction liquid. The reaction liquid was extracted using ethyl acetate, washed using water, and dried using magnesium sulfate. The solvent of the obtained extract was distilled using a rotary evaporator, refined using silica gel column chromatography, and compound C was obtained.

The obtained compound C was dissolved in dimethoxyethane, and 1.2 equivalent of 5′-formyl-2,2′-bithiophene-5-boronic acid, 0.05 equivalent of tetrakis triphenylphosphine palladium, and 2 equivalent of cesium carbonate were added thereto. After stirring for 12 hours at 80° C., water was added to the reaction liquid. The reaction liquid was extracted using ethyl acetate, washed using water, and dried using magnesium sulfate. The solvent of the obtained extract was distilled using a rotary evaporator, refined using silica gel, column chromatography, and compound D was obtained.

The obtained compound D was dissolved in acetic acid, and 3 equivalent of cyanoacetic acid and 5 equivalent of ammonium acetate were added thereto. After stirring for 6 hours at 100° C., water was added to the reaction liquid. The reaction liquid was extracted using ethyl acetate, washed using water, and dried using magnesium sulfate. The solvent of the obtained extract was distilled using a rotary evaporator, refined using silica gel column chromatography, and compound was obtained.

The structure of compound 15 was confirmed using the nuclear magnetic resonance spectrum and the mass spectrum.

### Synthesis Examples 2 to 21

The compounds 1, 2, 4, 8 to 10, 12, 16, 19, 20, 22, 24, 28, 30, 31, 34, 35, 37, 41, and 42 according to the present invention were synthesized by appropriately combining an aromatic electrophilic substitution reaction, an aromatic nucleophilic substitution reaction, a coupling reaction, a metathesis reaction, and the like with the synthesis method of Synthesis Example 1.

### Synthesis Examples 22 to 25

Compounds 101 to 104, which have different Xs in the General Formula (1), were synthesized by appropriately combining chemical reactions in the same manner as above Compounds 101 to 104 are shown below.

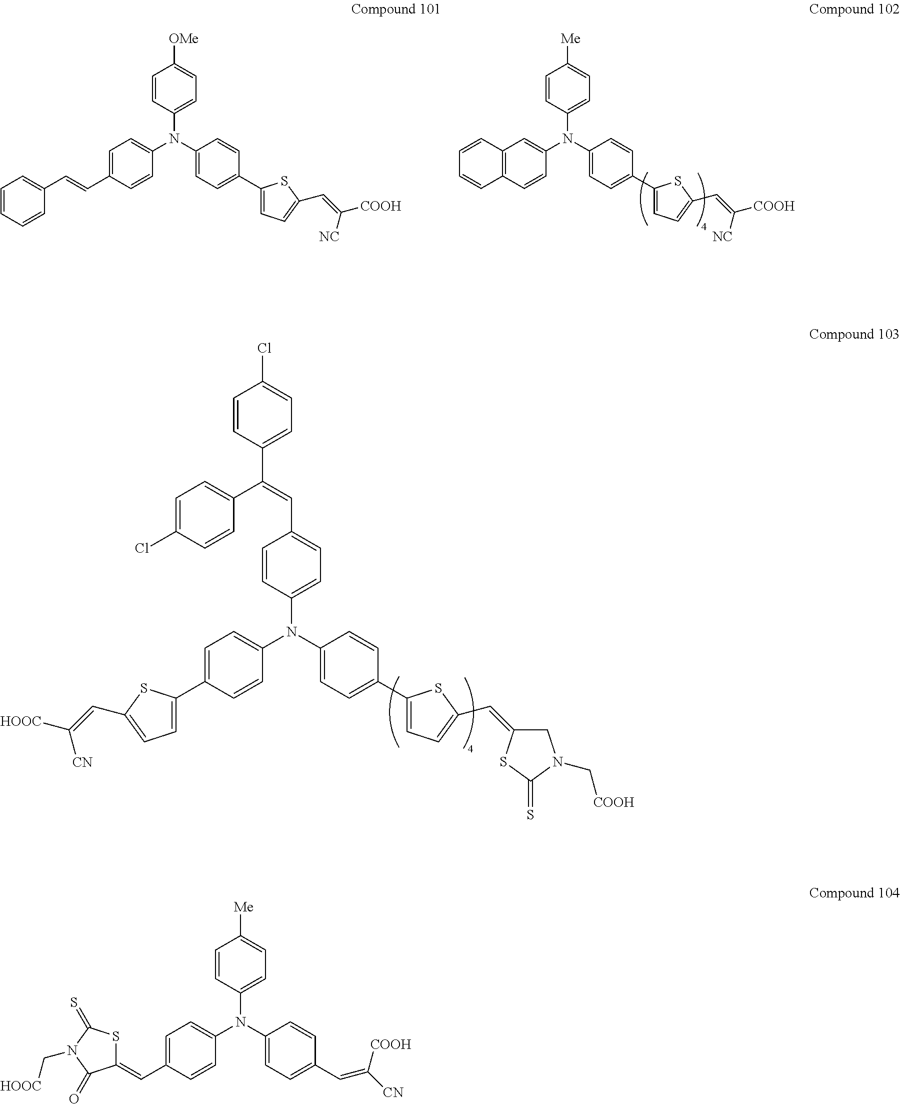

### Example 1

### Manufacturing of Photoelectric Conversion Element

The conductive support body was formed (film thickness: 0.1 mm, surface resistance value: 9.0 Ω/square) using a glass substrate (thickness: 1.0 mm) as the substrate, and fluorine doped tin oxide (FTO) (500 nm optical transmittance: 80%) as the first electrode. As the semiconductor, titanium oxide (anatase-type (powder), primary average particle diameter: 18 nm (the average value observed using an electron microscope)) was used, and a conductive glass substrate formed of the FTO was coated (coating area: 5×5 mm²) with titanium oxide paste which is a polyethyleneglycole dispersion liquid (titanium oxide concentration: 10% by weight) using the screen printing method and dried (for 3 minutes at 120° C.). After the coating and drying is repeated five times, firing is performed in an air atmosphere for 10 minutes at 200° C., then for 15 minutes at 500° C., and a titanium oxide thin film of a thickness of 13 μm was obtained. On this thin film, a polyethyleneglycole dispersed paste of the titanium oxide (anatase-type, primary average particle diameter: 400 nm (the average value observed using an electron microscope)) was further coated, dried and fired using a similar method, a titanium oxide thin film of a thickness of 3 μm was formed, and a semiconductor layer of a layer thickness of 16 μm was formed.

A sensitizing dye containing solution of 5×10⁻⁴ mol/L was prepared by dissolving the compound 1, which was synthesized in the Synthesis Example, in a mixed solvent of acetonitrile:tert-butylalcohol=1:1 (volume ratio). The photoelectric conversion layer was obtained by immersing the FTO glass substrate, on which the above semiconductor layer was formed, in the solution for 3 hours at room temperature (25° C.) and performing an adsorption treatment of the sensitization dye onto the semiconductor.

As the redox electrolyte, 0.6 mol/L of 1,2-dimethyl-3-propylimidazolium iodide, 0.1 mol/L of lithium iodide, and 0.05 mol/L of iodine were used, and as the organic base, an acetonitrile solution containing 0.5 mol/L of 4-tert-butylpyridine was used.

The photoelectric conversion element 1 was manufactured by using a glass plate in which platinum and chrome are deposited as the second electrode, and assembling using a clamp cell so that the layer thickness of the hole transport layer becomes 20 μm.

### Examples 2 to 23

### Manufacturing of Photoelectric Conversion Elements 2 to 21

Except for having used the compounds 2, 4, 8 to 10, 12, 15, 16, 19, 20, 22, 24, 28, 30, 33, 34, 35, 37, 41, and 42 which were synthesized as sensitizing dyes in the Synthesis Examples, the photoelectric conversion elements 2 to 21 were manufactured in the same manner as in Example 1.

### Comparative Examples 1 to 3

### Manufacturing of Photoelectric Conversion Elements 22 to 24

Except for having used the compounds 101 to 103 which were synthesized in the Synthesis Examples as sensitizing dyes, the photoelectric conversion elements 22 to 24 were manufactured in the same manner as in Example 1.

### Example 22

### Manufacturing of Photoelectric Conversion Element 25

The FTO conductive glass substrate described in Example 1 was coated (coating area: 5×5 mm²) with a polyethyleneglycole dispersed paste of titanium oxide (anatase-type, primary average particle diameter: 18 nm (the average value observed using an electron microscope)) using the screen printing method. Next, firing is performed in an air atmosphere for 10 minutes at 200° C., then for 15 minutes at 450° C., and a titanium oxide thin film of a thickness of 1.5 μm was obtained.

The sensitizing treatment of the semiconductor was performed using the same method as in Example 1.

A hole transport layer of a layer thickness of 10 μm was formed by preparing 0.17 mol/L of 2,2′,7,7′-tetrakis N,N′-di(4-methoxyphenyl)amine)-9,9′-spirobifluorene (OMeTAD) as the aromatic amine derivative, 0.33 mmol/L of N (PhBr)₃SbCl₆ and 15 mmol/L of Li [(CF₃SO₂)₂N] as the acceptor doping agent, and 50 mmol/L of a monochlorobenzene/acetonitrile solution containing 4-tert-butylpylidine (monochlorobenzene:acetonitrile=19:1) as the organic base, and spin coating them on the upper surface of the photoelectric conversion layer at a number of rotations of 1000 rpm.

The photoelectric conversion element 25 was manufactured by depositing 90 nm of gold (Au) using the vacuum deposition method and manufacturing the second electrode.

### Examples 23 to 31

### Manufacturing of Photoelectric Conversion Elements 26 to 34

Except for having used the compounds 2, 4, 8, 12, 22, 30, 34, 35 and 37, which were synthesized as sensitizing dyes in the Synthesis Examples, the photoelectric conversion elements 26 to 34 were manufactured in the same manner as in Example 22.

### Comparative Examples 4 to 6

### Manufacturing of Photoelectric Conversion Elements 35 to 37

Except for having used the compounds 101 to 1.03 which were synthesized as sensitizing dyes in the Synthesis Examples, the photoelectric conversion elements 35 to 37 were manufactured in the same manner as in Example 22.

### Example 32

### Manufacturing of Photoelectric Conversion Element 38

Except for having formed the hole transport layer using electrolytic polymerization, the photoelectric conversion element 38 was manufactured in the same manner as in Example 22. In the electrolytic polymerization, the photoelectric conversion element was immersed in an acetonitrile solution containing 2,2′-bis-3,4-ethylenedioxythiophene, which is a monomer which is a raw material of the hole transport material, and Li[(CF₃SO₂)₂N] (electrolytic polymerization solution; 2,2′-bis-3,4-ethylenedioxythiophene concentration: 1×10⁻³ mol/L, Li[(CF₃SO₂)₂N] concentration: 0.1 mol/L). The working electrode was set to the above semiconductor electrode, the counter electrode to the platinum wire, the reference electrode to Ag/Ag⁺ (AgNO₃ 0.01 M) of an impressed current density of 150 μA/cm², and the hold voltage to −0.3 V. The hole transport layer was formed on the above semiconductor electrode surface by holding a voltage for 15 minutes while light is irradiated from the semiconductor layer direction (using a xenon lamp, light strength 32 mW/cm², wavelengths of 520 nm or less are cut). The obtained semiconductor electrode/hole transport layer was washed using acetonitrile and dried.

Furthermore, the hole transport layer obtained here is a polymerized film which is insoluble in the solvent. Subsequently, the hole transport layer was immersed for 30 minutes in an acetonitrile solution containing 15×10⁻³ mol/L of Li[(CF₃SO₂)N] and 50×10⁻³ mol/L of tert-butylpyridine, in these proportions.

### Examples 33 to 41

### Manufacturing of Photoelectric Conversion Elements 39 to 47

Except for having used the compounds 2, 4, 8, 12, 22, 30, 34, 35 and 37, which were synthesized as sensitizing dyes in the Synthesis Examples, photoelectric conversion elements 39 to 47 were manufactured in the same manner as in Example 32.

### Comparative Examples 7 to 10

### Manufacturing of Photoelectric Conversion Elements 48 to 51

Except for having used the compounds 101 to 104 which were synthesized in the Synthesis Examples, photoelectric conversion e as sensitizing dyes elements 48 to 51 were manufactured in the same manner as in Example 32.

### [Evaluation of Photoelectric Conversion Element]

### <Preliminary Measurement of Photoelectric Conversion Efficiency>

The above photoelectric conversion element was irradiated with pseudo sunlight of a strength of 100 mW/cm² from a xenon lamp via an AM filter (AM −1.5) using a solar simulator (manufactured by EKO INSTRUMENTS CO., LTD.). Also, using an I-V tester, the current—voltage characteristics of the photoelectric conversion element at room temperature (25° C.) were measured, therefore the short circuit current density (Jsc), the open circuit voltage (Voc), and the fill factor (F.F.) were measured. The photoelectric conversion efficiency η (%) was calculated from the Formula 1 below based on these values.

η={(Voc×Jsc×F.F.)/P}×100 [Formula 1]

P: Incident Light Strength [mW/cm²]

### Voc: Open Circuit Voltage [V]

Jsc: Short Circuit Current Density [mA·cm^{-2],}

### F.F.: Fill Factor

### <Elution Durability Test>

In Examples 1 to 41 and Comparative Examples 1 to 10, before manufacturing the photoelectric conversion element using the photoelectric conversion layer obtained by adsorbing the sensitizing dye, the obtained photoelectric conversion layer was immersed for 3 hours at room temperature in a mixed solvent of acetonitrile:tert-butylalcohol=1:1, and enforced degradation was performed on the photoelectric conversion layer. Also, the photoelectric conversion element was manufactured using the photoelectric conversion layer to which enforced degradation was performed.

In regard to the obtained photoelectric conversion element, using the same method as that of the measurement of the above preliminary photoelectric conversion efficiency, the current—voltage characteristics of the photoelectric conversion element at room temperature (25° C.) were measured, therefore the short circuit current density (Jsc′), the open circuit voltage (Voc′), and the till factor (F.F.′) were measured. The photoelectric conversion efficiency η′ (%) was calculated in the same manner as in the above Formula 1 based on these values. Also, the ratio (η′/η) of the photoelectric conversion efficiency η′ after the elution degradation in relation to the photoelectric conversion efficiency η before degradation was obtained.

The evaluation results of the above tests of Examples 1 to 41 and Comparative Examples 1 to 1.0 are shown in Table 1.

TABLE I

| | PHOTOELECTRIC | | | | | | | | |
|---|---|---|---|---|---|---|---|---|---|
| | CONVERSION | SENSITIZING | Voc | Jsc | η | Voc′ | Jsc′ | η′ | |
| | ELEMENT | DYE | (mV) | mA · cm⁻² | (%) | (mV) | mA · cm⁻² | (%) | η′/η |
| EXAMPLE 1 | 1 | COMPOUND 1 | 630 | 10.1 | 4.1 | 630 | 9.8 | 4.0 | 0.98 |
| EXAMPLE 2 | 2 | COMPOUND 2 | 650 | 11.2 | 4.7 | 640 | 11.0 | 4.6 | 0.98 |
| EXAMPLE 3 | 3 | COMPOUND 4 | 680 | 12.5 | 5.6 | 670 | 12.2 | 5.4 | 0.96 |
| EXAMPLE 4 | 4 | COMPOUND 8 | 640 | 10.8 | 4.5 | 630 | 10.4 | 4.3 | 0.96 |
| EXAMPLE 5 | 5 | COMPOUND 9 | 670 | 11.8 | 5.2 | 670 | 11.7 | 5.1 | 0.98 |
| EXAMPLE 6 | 6 | COMPOUND 10 | 680 | 12.0 | 5.3 | 660 | 11.6 | 5.2 | 0.98 |
| EXAMPLE 7 | 7 | COMPOUND 12 | 700 | 12.3 | 5.6 | 680 | 12.1 | 5.5 | 0.98 |
| EXAMPLE 8 | 8 | COMPOUND 15 | 680 | 12.1 | 5.35 | 670 | 11.8 | 5.06 | 0.95 |
| EXAMPLE 9 | 9 | COMPOUND 16 | 660 | 11.5 | 4.9 | 650 | 11.0 | 4.6 | 0.94 |
| EXAMPLE 10 | 10 | COMPOUND 19 | 710 | 13.1 | 6.0 | 700 | 12.7 | 5.8 | 0.97 |
| EXAMPLE 11 | 11 | COMPOUND 20 | 690 | 12.8 | 5.7 | 680 | 12.5 | 5.5 | 0.96 |
| EXAMPLE 12 | 12 | COMPOUND 22 | 650 | 13.2 | 5.7 | 620 | 12.7 | 5.1 | 0.89 |
| EXAMPLE 13 | 13 | COMPOUND 24 | 640 | 10.8 | 4.5 | 640 | 10.3 | 4.0 | 0.89 |
| EXAMPLE 14 | 14 | COMPOUND 28 | 690 | 12.0 | 5.4 | 680 | 11.7 | 5.2 | 0.96 |
| EXAMPLE 15 | 15 | COMPOUND 30 | 620 | 9.6 | 4.0 | 610 | 8.9 | 3.5 | 0.88 |
| EXAMPLE 16 | 16 | COMPOUND 33 | 680 | 11.1 | 4.9 | 670 | 11.0 | 4.8 | 0.98 |
| EXAMPLE 17 | 17 | COMPOUND 34 | 700 | 13.2 | 5.0 | 680 | 13.0 | 5.7 | 0.95 |
| EXAMPLE 18 | 18 | COMPOUND 35 | 690 | 12.8 | 5.7 | 670 | 12.5 | 5.4 | 0.95 |
| EXAMPLE 19 | 19 | COMPOUND 37 | 690 | 12.5 | 5.6 | 680 | 12.2 | 5.4 | 0.96 |
| EXAMPLE 20 | 20 | COMPOUND 41 | 640 | 11.0 | 4.6 | 630 | 10.5 | 4.3 | 0.93 |
| EXAMPLE 21 | 21 | COMPOUND 42 | 630 | 10.8 | 4.4 | 610 | 9.9 | 3.8 | 0.86 |
| COMPATATIVE | 22 | COMPOUND 101 | 640 | 8.2 | 3.4 | 590 | 6.4 | 2.3 | 0.68 |
| EXAMPLE 1 | | | | | | | | | |
| COMPATATIVE | 23 | COMPOUND 102 | 650 | 8.8 | 3.8 | 610 | 7.1 | 2.6 | 0.68 |
| EXAMPLE 2 | | | | | | | | | |
| COMPATATIVE | 24 | COMPOUND 103 | 660 | 9.8 | 4.0 | 630 | 8.1 | 3.1 | 0.78 |
| EXAMPLE 3 | | | | | | | | | |
| EXAMPLE 22 | 25 | COMPOUND 1 | 730 | 8.1 | 3.8 | 720 | 8.0 | 3.7 | 0.97 |
| EXAMPLE 23 | 26 | COMPOUND 2 | 740 | 8.9 | 4.3 | 730 | 8.8 | 4.2 | 0.98 |
| EXAMPLE 24 | 27 | COMPOUND 4 | 780 | 9.6 | 4.9 | 760 | 9.4 | 4.6 | 0.94 |
| EXAMPLE 25 | 28 | COMPOUND 8 | 730 | 9.1 | 4.3 | 720 | 8.8 | 4.1 | 0.95 |
| EXAMPLE 26 | 29 | COMPOUND 12 | 750 | 8.6 | 4.2 | 730 | 8.4 | 4.0 | 0.95 |
| EXAMPLE 27 | 30 | COMPOUND 22 | 710 | 9.0 | 4.2 | 700 | 9.0 | 4.1 | 0.98 |
| EXAMPLE 28 | 31 | COMPOUND 30 | 700 | 8.2 | 3.8 | 670 | 7.8 | 3.4 | 0.89 |
| EXAMPLE 29 | 32 | COMPOUND 34 | 760 | 9.8 | 4.8 | 750 | 9.7 | 4.6 | 0.96 |
| EXAMPLE 30 | 33 | COMPOUND 35 | 740 | 8.8 | 4.2 | 720 | 8.7 | 4.1 | 0.98 |
| EXAMPLE 31 | 34 | COMPOUND 37 | 720 | 8.3 | 3.9 | 700 | 8.0 | 3.6 | 0.92 |
| COMPATATIVE | 35 | COMPOUND 101 | 700 | 5.1 | 2.4 | 640 | 3.9 | 1.6 | 0.67 |
| EXAMPLE 4 | | | | | | | | | |
| COMPATATIVE | 36 | COMPOUND 102 | 710 | 6.2 | 2.9 | 660 | 5.0 | 2.0 | 0.69 |
| EXAMPLE 5 | | | | | | | | | |
| COMPATATIVE | 37 | COMPOUND 103 | 730 | 7.2 | 3.6 | 700 | 6.5 | 2.8 | 0.78 |
| EXAMPLE 6 | | | | | | | | | |
| EXAMPLE 32 | 38 | COMPOUND 1 | 830 | 7.3 | 4.1 | 820 | 7.2 | 3.8 | 0.93 |
| EXAMPLE 33 | 39 | COMPOUND 2 | 860 | 7.6 | 4.3 | 850 | 7.4 | 4.1 | 0.95 |
| EXAMPLE 34 | 40 | COMPOUND 4 | 900 | 8.0 | 4.8 | 880 | 7.7 | 4.4 | 0.92 |
| EXAMPLE 35 | 41 | COMPOUND 8 | 880 | 7.5 | 4.3 | 860 | 7.3 | 4.1 | 0.95 |
| EXAMPLE 36 | 42 | COMPOUND 12 | 860 | 7.1 | 3.8 | 860 | 6.5 | 3.6 | 0.95 |
| EXAMPLE 37 | 43 | COMPOUND 22 | 810 | 8.2 | 4.3 | 800 | 7.8 | 4.1 | 0.95 |
| EXAMPLE 38 | 44 | COMPOUND 30 | 820 | 7.6 | 4.1 | 800 | 6.8 | 3.6 | 0.88 |
| EXAMPLE 39 | 45 | COMPOUND 34 | 860 | 8.9 | 4.9 | 850 | 8.3 | 4.6 | 0.94 |
| EXAMPLE 40 | 46 | COMPOUND 35 | 880 | 8.4 | 4.8 | 880 | 7.9 | 4.5 | 0.94 |
| EXAMPLE 41 | 47 | COMPOUND 37 | 880 | 8.0 | 4.6 | 850 | 7.6 | 4.2 | 0.91 |
| COMPATATIVE | 48 | COMPOUND 101 | 750 | 3.9 | 1.9 | 700 | 2.6 | 1.2 | 0.63 |
| EXAMPLE 7 | | | | | | | | | |
| COMPATATIVE | 49 | COMPOUND 102 | 720 | 2.8 | 1.3 | 690 | 2.0 | 0.9 | 0.69 |
| EXAMPLE 8 | | | | | | | | | |
| COMPATATIVE | 50 | COMPOUND 103 | 810 | 6.2 | 3.3 | 780 | 5.2 | 2.6 | 0.79 |
| EXAMPLE 9 | | | | | | | | | |
| COMPATATIVE | 51 | COMPOUND 104 | 860 | 8.9 | 4.9 | 800 | 6.5 | 3.1 | 0.63 |
| EXAMPLE 10 | | | | | | | | | |

From the results of Table 1, when the photoelectric conversion element according to the present invention was used, the absorption wavelength region was wavelength lengthened due to an expansion of the π conjugated system of the sensitizing dye, and the short circuit, current density (Jsc), the open circuit voltage (Voc), and the photoelectric conversion efficiency in relation to the pseudo sunlight exhibited high values (Examples 1 to 21). The result was the same even when the hole transport layer was changed to a hole transport layer containing a monomer, and a hole transport layer containing a polymer which was formed by electrolytic polymerization (Examples 22 to 41).

In addition, from the value of η′/η of the elution durability evaluation, in the photoelectric conversion element using the photoelectric conversion element according to the present invention, the short circuit current density (Jsc), the open circuit voltage (Voc), and the photoelectric conversion efficiency in relation to the pseudo sunlight of the photoelectric conversion element which was manufactured after the enforced degradation were maintained, η′/η exhibited a high value, and a favorable result was exhibited in the elution durability test (Examples 1 to 21). Meanwhile, in the above Chemical Formula (1), when a compound in which the Xs are different was used, the short circuit current density (Jsc), the open circuit voltage (Voc), and the photoelectric conversion efficiency in relation to the pseudo sunlight after the elution test decreased, η′/η exhibited a low value, and the result of the elution durability test was poor (Comparative Examples 1 to 3). The result was the same even when the hole transport layer was changed to a hole transport layer containing a monomer, and a hole transport layer containing a polymer which was formed by electrolytic polymerization (Examples 22 to 41 and Comparative Examples 4 to 10).

From these results, it may be understood that the dye of the photoelectric conversion element according to the present invention has a high tolerance to dye desorption, and high stability in relation to the degradation conditions Therefore, by the Xs being the same, in other words, the sensitizing dye incorporating the same adsorption groups, the durability of the photoelectric conversion element is improved. The reason is not clear, however, it is considered to have a stable adsorption power since the two adsorption groups may uniformly adsorb onto the semiconductor.

According to the above results, it may be understood that a photoelectric conversion element containing the sensitizing dye according to the present invention has excellent photoelectric conversion efficiency, and high durability.

What is claimed is:

1. A photoelectric conversion element comprising:
a substrate;
a first electrode;
a photoelectric conversion layer containing a semiconductor and a sensitizing dye;
a hole transport layer; and
a second electrode,
wherein the sensitizing dye is represented by the following Chemical Formula (1) 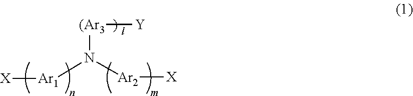
wherein, Ar₁, Ar₂, and Ar₃ are each independently a divalent aromatic ring-containing group, or a divalent unsaturated hydrocarbon group, and, Ar₁, Ar₂, and Ar₃ which are bonded to the nitrogen atom are a divalent aromatic ring-containing group, provided that Ar₁, Ar₂, and Ar₃ may form a ring together,
n is an integer of from 1 to 9, and when n is 2 or greater, the respective Ar₁s may be different from each other, m is an integer of from 1 to 9, and when m is 2 or greater, the respective Ar₂s may be different from each other, 1 is an integer of from 1 to 5, and when 1 is 2 or greater, the respective Ar₃s may be different from each other, and in this case, m+n≧3 is satisfied, and when m=n, —(Ar₁)— and —(Ar₂)ₘ— are different from each other,
X is a monovalent substituent containing an acidic group, and
Y is a hydrogen atom or a monovalent substituent.

2. The photoelectric conversion element of claim 1, wherein at least one of the Ar₁, Ar₂, and Ar₃ has at least one thiophene ring structure.

3. The photoelectric conversion element of claim 2, wherein the thiophen ring binds to the X or the Y.

4. The photoelectric conversion element of claim 1, wherein at least one of the Ar₁, Ar₂, and Ar₃ has at least one substituent selected from the group consisting of alkyl groups of from C1 to C20, alkoxy groups of from C1 to C8, and halogen atoms.

5. The photoelectric conversion element of claim 1,
wherein the sensitizing dye is represented by the Chemical Formula (2) below: 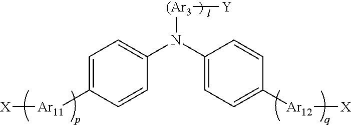
wherein, Ar₁₁ and Ar₁₂ are each independently a divalent aromatic ring-containing group or a divalent unsaturated hydrocarbon group,
p is an integer of from 0 to 8, and in this case, when p is 2 or greater, the respective Ar₁₁s may be different from each other, q is an integer of from 0 to 8, and in this case, when q is 2 or greater, the respective Ar₁₂s may be different from each other, p+q≧1 is satisfied, and when p=q, —(Ar₁₁)ₚ— and —(Ar₁₂)_{q}— are different from each other.

6. The photoelectric conversion element of claim 5, wherein at least one of the Ar₃, Ar₁₁, and Ar₁₂ has at least one thiophen ring structure.

7. The photoelectric conversion element of claim 6, wherein the thiophen ring binds to the X or the Y.

8. The photoelectric conversion element of claim 5, wherein at least one of the Ar₃, Ar₁₁, and Ar₁₂ has at least one substituent selected from the group consisting of alkyl groups of from C1 to C20, alkoxy groups of from C1 to C8 and halogen atoms.

9. The photoelectric conversion element of claim 1, wherein the semiconductor is titanium oxide.

10. A solar battery comprising the photoelectric conversion element set forth in claim 1.
